(19) United States
(12) Patent Application Publication
(10) Pub. No.: US 2024/0363617 A1
(43) Pub. Date: Oct. 31, 2024

(54) ELECTROSTATIC DISCHARGE USING BACKSIDE POWER DISTRIBUTION NETWORK

(71) Applicant: INTERNATIONAL BUSINESS MACHINES CORPORATION, ARMONK, NY (US)

(72) Inventors: Terence Hook, Jericho Center, VT (US); Brent A. Anderson, Jericho, VT (US); Ruilong Xie, Niskayuna, NY (US); Anthony I. Chou, Guilderland, NY (US); John Christopher Arnold, North Chatham, NY (US); Nicholas Alexander POLOMOFF, Hopewell Junction, NY (US)

(21) Appl. No.: 18/306,487

(22) Filed: Apr. 25, 2023

(51) Int. Cl. H01L 27/02; H01L 21/84; H02H 9/04

(52) U.S. Cl. CPC H01L 27/0255; H01L 21/84; H01L 27/0292; H02H 9/046

(57) ABSTRACT

An ESD protection device is disclosed that uses a BSPDN to provide potential(s) to the ESD protection device. The utilization of the BSPDN reduces resistance drops induced during high current ESD events, which results in robust ESD protection. The utilization of the BSPDN also reduces the footprint area of the ESD protection circuit relative to known ESD protection devices that utilize respective frontside contacts to VDD, VSS, and I/O. Further, the disclosed ESD protection circuit may utilize the same or similar structures as that are used by microdevices (e.g., transistors, or the like) within the semiconductor IC device, which may decrease fabrication complexities thereof.

### BACKGROUND

Various embodiments of the present disclosure generally relate to semiconductor integrated circuit (IC) device fabrication operations and resulting semiconductor IC devices. More specifically the various embodiments of the present disclosure relate to an electrostatic discharge (ESD) protection structure and/or circuit that uses a backside power distribution network (BSPDN).

Conventional semiconductor IC devices, such as integrated circuits (ICs), or the like, incorporate planar field effect transistors (FETs) in which current flows through a semiconducting channel between a source and a drain, in response to a voltage applied to a control gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes.

One particularly technology change entailed re-designing the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanowires, nanosheets, or the like, that are isolated from the substrate. In the GAA FET, channel surfaces are in respective contact with the source and drain and other respective channel surfaces are in contact with and surrounded by the gate.

ESD is a sudden and momentary flow of electric current between two electrically charged objects caused by contact, an electrical short or dielectric breakdown. A buildup of static electricity can be caused by tribocharging or by electrostatic induction. ESD occurs when differently charged objects are brought close together or when the dielectric between them breaks down, often creating a visible spark.

Many electronic components, especially semiconductor IC devices, can be damaged by ESD. Sensitive components need to be protected during and after manufacture, during shipping and device assembly, and in the finished device. Manufacturers of semiconductor IC device may integrate ESD protection devices into the semiconductor IC device itself to reduce the likelihood of ESD failures.

A diode may be used as an ESD protection device. In a typical dual-diode ESD protection circuit, two ESD diodes are connected to power, to ground, and to an input/output (I/O) pad front the frontside of the semiconductor IC device. These typical dual-diode ESD protection circuits are also typically cooperated with a turn-on efficient power rail ESD clamp circuit to discharge ESD current.

### SUMMARY

In an embodiment of the present disclosure, an electrostatic discharge (ESD) protection device is presented. The ESD protection device includes a first diode and a second diode. The first diode includes a first anode and a first cathode that is connected to a first power rail within a backside power distribution network (BSPDN). The second diode includes a second cathode and second anode that is connected to a second power rail within the BSPDN. The utilization of the BSPDN reduces resistance drops, relative to known ESD protection devices that utilize frontside contacts to VDD, VSS, and I/O, to induced during high current ESD events, which results in robust ESD protection. The utilization of the BSPDN also reduces the footprint area relative to known ESD protection devices that utilize respective frontside contacts to VDD, VSS, and I/O, which may provide for continued semiconductor IC device scaling.

In an example, the BSPDN provides a VDD potential to the first power rail and provides a VSS potential to the second power rail. The VDD potential and the VSS potential may provide proper potential diode biasing for the ESD protection device.

In an example, the ESD protection device further includes a frontside back end of the line (BEOL) conductive structure electrically connected to the first anode and to the second cathode. The frontside BEOL may provide for a frontside BEOL conductive feature to electrically connect the diodes of the ESD protection device.

In an example, the frontside BEOL conductive structure may provide a signal on the I/O to the ESD protection device. The I/O may provide a signal or time dependent variable potential to the diodes of the ESD protection device for proper ESD protection device functioning.

In an example, the ESD protection device further includes a substrate. The ESD protection device may be an on semiconductor IC device with one portion of the substrate of the semiconductor IC device being used to fabricate the ESD protection device while another portion of the substrate of the semiconductor IC device may be a logic region in which numerous logic device, such as transistors, may be fabricated which may reduce overall semiconductor IC device fabrication complexities.

In an example, the first diode includes a first diode stack of doped regions within the substrate and the second diode includes a second diode stack of doped regions within the substrate. In other words, the diodes may be fabricated entirely within the substrate for increase diode reliability.

In an example, the first diode stack includes a lightly doped n-type well. In other words, the first diode n-type well may be fabricated entirely within the substrate for increase diode reliability.

In an example, a highly doped p-type epitaxially grown region is vertically above the first diode stack upon a top surface of the substrate. In other words, an additional p-type structure that may be fabricated entirely above the substrate, moving the first diode junction to the top surface of the substrate, which may allow for a vertically thinner substrate and a reduction of thickness of the semiconductor IC device. In other embodiments, the first diode junction is entirely within the substrate which may achieve relatively better diode ideality and increased diode junction area in same footprint area.

In an example, the second diode stack includes a lightly doped p-type well. In other words, the first diode n-type well may be fabricated entirely within the substrate for increase diode reliability.

In an example, a highly doped n-type epitaxially grown region is vertically above the second diode stack upon the top surface of the substrate. In other words, an additional n-type structure that may be fabricated entirely above the substrate, moving the second diode junction to the top surface of the substrate, which may allow for a vertically thinner substrate and a reduction of thickness of the semiconductor IC device. In other embodiments, the second diode junction is entirely within the substrate which may achieve relatively better diode ideality and increased diode junction area in same footprint area.

In an example, the ESD protection device further includes a first frontside contact upon the highly doped p-type epitaxially grown region and a second frontside contact upon the highly doped n-type epitaxially grown region. These contacts may be like the frontside contacts utilized in the logic region and may therefore reduce overall semiconductor IC device fabrication complexities.

In an example, the frontside BEOL conductive structure may be connected to the first frontside contact and to the second frontside contact. These frontside BEOL conductive structure may be indirectly connected to the diodes through the first frontside contact and to the second frontside contact to provide the I/O signal or time dependent variable potential to the diodes of the ESD protection device for proper ESD protection device functioning.

In an example, the first diode stack further includes a highly doped n-type region below the lightly doped n-type well within the substrate and the second diode stack further includes a highly doped p-type region below the lightly doped p-type well within the substrate. In other words, the first diode and second diode may be fabricated entirely within the substrate for increase diode reliability. These backside contacts may be like the backside side contacts utilized in the logic region and may therefore reduce overall semiconductor IC device fabrication complexities.

In an example, the ESD protection device further includes a first backside contact upon the highly doped n-type region. In this example, the highly doped n-type region may be the first cathode. The first backside contact may provide power potential such as VDD, VSS, to the first diode for proper ESD protection device functioning. In using the backside of the semiconductor IC device to provide power potential to the ESD protection device the overall footprint of the ESD protection device may be significantly smaller (e.g., two times smaller, etc.) relative to known ESD protection devices.

In an example, the ESD protection device further includes a second backside contact upon the highly doped p-type region. In this example, the highly doped p-type region is the second anode. The second backside contact may provide power potential such as VSS. VDD, to the second diode for proper ESD protection device functioning. In using the backside of the semiconductor IC device to provide power potential to the ESD protection device the overall footprint of the ESD protection device may be significantly smaller (e.g., two times smaller, etc.) relative to known ESD protection devices.

In an example, the first backside side contact is connected to the first power rail and the second backside side contact is connected to the second power rail. In using the backside of the semiconductor IC device to provide power potential to the ESD protection device the overall footprint of the ESD protection device may be significantly smaller (e.g., two times smaller, etc.) relative to known ESD protection devices.

In another embodiment of the disclosure, a semiconductor integrated circuit (IC) device is presented. The Semiconductor IC device includes a logic region and an electrostatic discharge (ESD) region. The logic region includes a first source/drain (S/D), (e.g., a source or a drain, respectively), a second S/D (e.g., a drain or a source, respectively), one or more nanolayer channels connected to the first S/D and connected to the second S/D, and a gate structure connected to the one or more nanolayer channels. The ESD region includes a first diode and a second diode. The first diode includes a first anode and a first cathode that is connected to a first power rail within a backside power distribution network (BSPDN). The second diode includes a second cathode and second anode that is connected to a second power rail within the BSPDN. The utilization of the BSPDN reduces resistance drops induced during high current ESD events, which results in robust ESD protection. The utilization of the BSPDN also reduces the footprint area of the ESD protection device, relative to known ESD protection circuits that utilize respective frontside contacts to VDD, VSS, and I/O, which may provide for continued semiconductor IC device scaling.

In an example, the BSPDN provides a VDD potential to the first power rail and provides a VSS potential to the second power rail. The VDD potential, VSS potential provides for proper ESD protection device functioning.

In an example, the semiconductor IC device further includes a frontside back end of the line (BEOL) conductive structure electrically connected to the first anode, to the second cathode, and to the second S/D. The use of the frontside BEOL to connect the diodes effectively splits the contact area needed between the BSPDN and the frontside BEOL and may relatively reduce the overall footprint of the ESD protection device (e.g., two times smaller, etc.) relative to known ESD protection devices.

In an example, the ESD region further includes a substrate. The ESD protection device may be an on semiconductor IC device with one portion of the substrate of the semiconductor IC device being used to fabricate the ESD protection device while another portion of the substrate of the semiconductor IC device may be a logic region in which numerous logic device, such as transistors, may be fabricated which may reduce overall semiconductor IC device fabrication complexities.

In an example, the first diode includes a first diode stack of doped regions within the substrate and the second diode includes a second diode stack of doped regions within the substrate. In other words, the diodes may be fabricated entirely within the substrate for increase diode reliability.

In an example, the first diode stack includes a lightly doped n-type well. In other words, the diodes may be fabricated entirely within the substrate for increase diode reliability.

In an example, the ESD region further includes a highly doped p-type epitaxially grown region vertically above the first diode stack upon a top surface of the substrate. In other words, an additional p-type structure that may be fabricated entirely above the substrate, moving the first diode junction to the top surface of the substrate, which may allow for a vertically thinner substrate and a reduction of thickness of the semiconductor IC device. In other embodiments, the first diode junction is entirely within the substrate which may achieve relatively better diode ideality and increased diode junction area in same footprint area.

In an example, the second diode stack includes a lightly doped p-type well. In other words, the diodes may be fabricated entirely within the substrate for increase diode reliability.

In an example, the ESD region further includes a highly doped n-type epitaxially grown region vertically above the second diode stack upon the top surface of the substrate. In other words, an additional n-type structure that may be fabricated entirely above the substrate, moving the second diode junction to the top surface of the substrate, which may allow for a vertically thinner substrate and a reduction of thickness of the semiconductor IC device. In other embodiments, the second diode junction is entirely within the substrate which may achieve relatively better diode ideality and increased diode junction area in same footprint area.

The disclosed ESD protection device may utilize the same or similar structures as that are used by the logic region (e.g., the first S/D region, the second S/D region, the highly doped p-type epitaxially grown region, and/or the highly doped n-type epitaxially grown region may be formed in the same or similar fabrication stage(s)) within the semiconductor IC device, which may decrease fabrication complexities thereof.

In an example, the ESD region further includes a first frontside contact upon the highly doped p-type epitaxially grown region and a second frontside contact upon the highly doped n-type epitaxially grown region. The use of the frontside BEOL to connect the diodes effectively splits the contact area needed between the BSPDN and the frontside BEOL and may relatively reduce the overall footprint of the ESD protection device (e.g., two times smaller, etc.) relative to known ESD protection devices. Further the frontside contacts may be similar to those used in the logic region and may reduce semiconductor IC device fabrication complexities.

In an example, the logic region further includes a third frontside contact between the second S/D and the frontside BEOL conductive structure. The use of the frontside BEOL to connect the diodes effectively splits the contact area needed between the BSPDN and the frontside BEOL and may relatively reduce the overall footprint of the ESD protection device (e.g., two times smaller, etc.) relative to known ESD protection devices. Further the frontside contacts may be similar to those used in the logic region and may reduce semiconductor IC device fabrication complexities.

In an example, the first diode stack further includes a highly doped n-type region below the lightly doped n-type well within the substrate and the second diode stack further includes a highly doped p-type region below the lightly doped p-type well within the substrate. In other words, the diodes may be fabricated entirely within the substrate for increase diode reliability.

In an example, the ESD region further includes a first backside side contact upon the highly doped n-type region and a second backside contact upon the highly doped p-type region. The first backside contact may provide power potential such as VDD, VSS, to the first diode for proper ESD protection device functioning. In using the backside of the semiconductor IC device to provide power potential to the ESD protection device the overall footprint of the ESD protection device may be significantly smaller (e.g., two times smaller, etc.) relative to known ESD protection devices.

In an example, the logic region further includes a third backside contact upon the first S/D region. The backside contacts within the ESD region may be similar to those used in the logic region and may reduce semiconductor IC device fabrication complexities.

These and other embodiments, features, aspects, and advantages will become better understood with reference to the following description, appended claims, and accompanying drawings.

### BRIEF DESCRIPTION OF THE DRAWINGS

FIG. 1 depicts a semiconductor IC device that includes an ESD protection device, such as a circuit or structure, that uses a BSPDN, in accordance with one or more embodiments of the disclosure.

FIG. 2 through FIG. 21 depict fabrication views of a semiconductor IC device that includes an ESD protection device that uses a BSPDN, in accordance with one or more embodiments of the disclosure.

FIG. 22 depicts a flow diagram illustrating a semiconductor IC device fabrication method to fabricate a semiconductor IC device that includes an ESD protection device that uses a BSPDN, in accordance with one or more embodiments of the disclosure.

FIG. 23 depicts an alternative dopant or well configuration of a substrate of a semiconductor IC device that includes an ESD protection circuit that uses a BSPDN.

FIG. 24 depicts a semiconductor IC device that includes a diode structure and circuit that uses a BSPDN, in accordance with one or more embodiments of the disclosure.

### DETAILED DESCRIPTION

Embodiments of the disclosure recognize that protecting semiconductor IC devices from ESD is desirable. As such, the present disclosure provides a fabrication scheme to fabricate a semiconductor IC device that includes an ESD protection circuit that uses a BSPDN. The utilization of the BSPDN reduces resistance drops induced during high current ESD events, which results in robust ESD protection. The utilization of the BSPDN also reduces the footprint area of the ESD protection circuit relative to known ESD protection circuits that utilize respective frontside contacts to VDD, VSS, and I/O. Further, the disclosed ESD protection circuit may utilize the same or similar structures as that are used by microdevices (e.g., transistors, or the like) within the semiconductor IC device, which may decrease fabrication complexities thereof.

Although this detailed description includes examples of how embodiments of the disclosure can be implemented to form an exemplary semiconductor IC device with GAA FETs, implementation of the teachings recited herein are not necessarily limited to a particular type of FET structure or combination of materials depicted or described. Rather, embodiments of the present disclosure are capable of being implemented in conjunction with other transistor types or materials, now known or later developed, wherein it is desirable for the semiconductor IC device to include an ESD protection circuit that uses a BSPDN.

For the sake of brevity, conventional techniques related to semiconductor IC device fabrication may or may not be described in detail herein. Moreover, the various tasks and process steps described herein can be incorporated into a more comprehensive procedure or process having additional steps or functionality not described in detail herein. Various steps in the manufacture of semiconductor IC devices are well known and so, in the interest of brevity, many conventional steps will only be mentioned briefly herein or will be omitted entirely without providing the well-known process details.

In general, the various processes used to form a semiconductor IC device that will be packaged into a final or packaged IC, fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion, by ion implantation, or otherwise incorporating applicable impurities. These doping processes are followed by furnace annealing or by rapid thermal annealing (RTA). Annealing serves to activate the implanted dopants. Films of both conductors (e.g., polysilicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to a description of technologies that are more specifically relevant to the present disclosure, transistors are a type of microdevice commonly found in a wide variety of semiconductor IC devices. Typical semiconductor IC devices may be formed using active regions of a wafer. The active regions are defined by isolation regions used to separate and electrically isolate adjacent semiconductor IC devices. For example, in an IC having a plurality of GAA FETs, each GAA FET has a source and a drain that are formed in an active region of a semiconductor layer by implanting or otherwise incorporating n-type or p-type impurities in the respective source and the drain material. Disposed between the source and the drain is a channel (or body) region. Disposed around the channel is the gate. The gate and the channel are spaced apart by a dielectric layer.

GAA FETs may be fabricated using so-called complementary metal oxide semiconductor (CMOS) fabrication technologies. In general, CMOS is a technology that uses complementary and symmetrical pairs of p-type and n-type MOSFETs to implement logic functions. The channel region connects the source and the drain, and electrical current flows through the channel region from the source to the drain. The electrical current flow is induced in the channel region by a voltage applied at the gate electrode.

The wafer footprint of a GAA FET is related to the electrical conductivity of the channel material. If the channel material has a relatively high conductivity, the GAA FET can be made with a correspondingly smaller wafer footprint. A known method of increasing channel conductivity and decreasing GAA FET size is to form the channel as a nanostructure, such as a nanowire or nanosheet. These GAA FETs provide a relatively small FET footprint by forming the channel as a series of vertical nanostructures.

In a known GAA configuration, a nanostructure-based FET includes a source region, a drain region, and stacked nanostructure channels between the source and drain regions. A gate surrounds the stacked nanostructure channels and regulates electron and hole flow through the nanostructure channels between the source and drain regions. GAA FETs may be fabricated by forming alternating layers of channel nanostructure and sacrificial nanostructure layers. The sacrificial nanostructure layers are released from the channel nanostructures before the GAA FET device is finalized. For n-type GAA FETs, the channel nanostructure layers may be silicon (Si) and the sacrificial nanostructure layers may be silicon germanium (SiGe). For p-type GAA FETs, in some implementations, the channel nanostructure layers may be SiGe and the sacrificial nanostructure layers may be Si. In other implementations, p-type GAA FETs, the channel nanostructure may be Si, and the sacrificial nanostructure can be SiGe. In some implementations, the channel nanostructure layers may initially be Si and can be converted to SiGe or other material, after sacrificial nanostructure layers are removed.

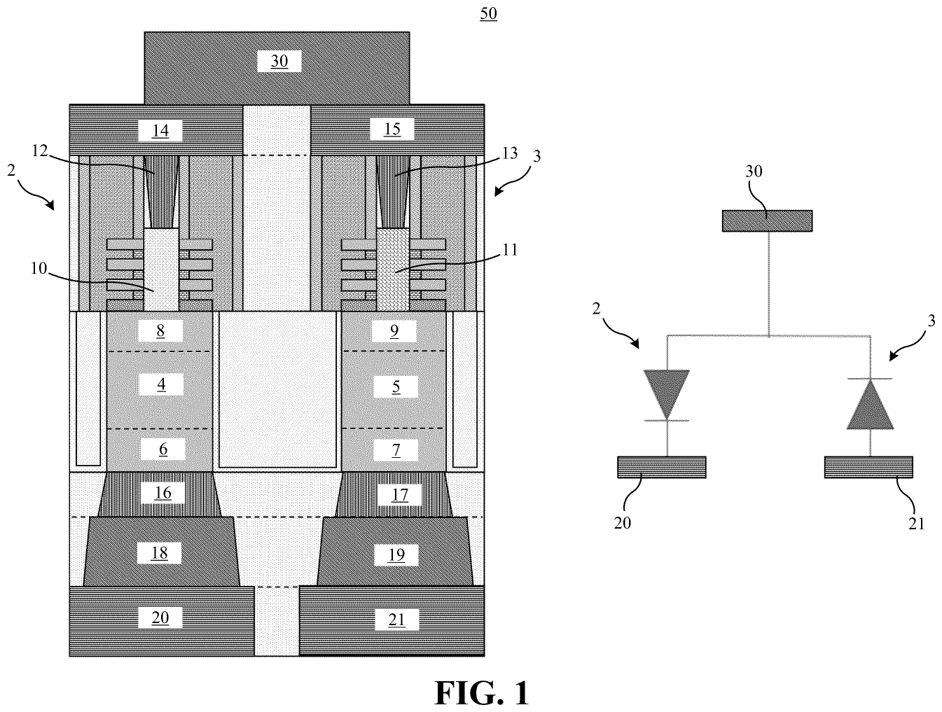

Turning now to a more detailed description an embodiment of the disclosure, FIG. 1 depicts a semiconductor IC device that includes an ESD protection structure and circuit 50 that uses a BSPDN, in accordance with one or more embodiments of the disclosure. The ESD protection structure and circuit 50 includes a diode 2 and diode 3. The cathode of diode 2 is connected to a VDD structure 20 within the BSPDN and the anode of diode 3 is connected to a VSS structure 21 within the BSPDN. The anode of diode 2 and the cathode of diode 3 are connected indirectly or directly to a same conductive pathway within the BEOL structure 30, such as an the same I/O pad, the same I/O wire, or the like. The ESD protection structure and circuit 50 may be cooperated with a turn-on efficient power-rail ESD clamp circuit (not shown) to discharge ESD current.

Diode 2 may include an N− well substrate region 4, an N+ substrate region 6, a P+ substrate region 8, and/or a P+ device region 10. Similarly, diode 3 may include a P− well substrate region 5, a P+ substrate region 7, a N+ substrate region 9, and/or a N+ device region 11. N− well substrate region 4 and P− well substrate region 5 may be respective doped regions of a substrate.

The N+ substrate region 6 may be vertically below and adjacent to the N− well substrate region 4 and the P+ substrate region 8 may be vertically above and adjacent to the N− well substrate region 4. In this manner, the N+ substrate region 6, N− well substrate region 4, and the P+ substrate region 8 may form a vertical diode stack. Similarly, the P+ substrate region 7 may be vertically below and adjacent to the P-well substrate region 5 and the N+ substrate region 9 may be vertically above and adjacent to the P-well substrate region 5. In this manner, the P+ substrate region 7, P− well substrate region 5, and the N+ substrate region 9 may form a vertical diode stack. These respective substrate regions that are not in the same diode stack may be separated by one or more shallow trench isolation (STI) regions. P+ device region 10 may be vertically above and connected to the P+ substrate region 8 and N+ device region 11 may be vertically above and connected to the N+ substrate region 9.

P+ device region 10 may be connected to a frontside back end of the line (BEOL) wiring network 14 by a contact 12. N+ device region 11 may be connected to a frontside BEOL wiring network 15 by a contact 13. The BEOL wiring network 14 and the BEOL wiring network 15 are generally within the same frontside BEOL network. In one implementation, BEOL wiring network 14 and BEOL wiring network 15 are the same wire or a same node within the frontside BEOL wiring network. In an alternative implementation, BEOL wiring network 14 and BEOL wiring network 15 may be different wires or different nodes within the frontside BEOL wiring network that are connected by an I/O pad 30, as depicted.

N+ substrate region 6 may be connected to a backside power wire 18 by a contact 16 and P+ substrate region 7 may be connected to a backside power wire 19 by a contact 17. Backside power wire 18 and backside power wire 19 are a part of the BSPDN of the ESD protection structure of the ESD protection structure and circuit 50. Backside power wire 18 and backside power wire 19 may typically have different potentials. For example, backside power wire 18 may be at VDD and backside power wire 19 may be at VSS. Backside power wire 18 may be connected to other backside power wire(s) or structure(s) 20 of the same relative potential, within the BSPDN. Likewise, backside power wire 19 may be connected to other backside power wire(s) or structure(s) 21 of the same relative potential, within the BSPDN.

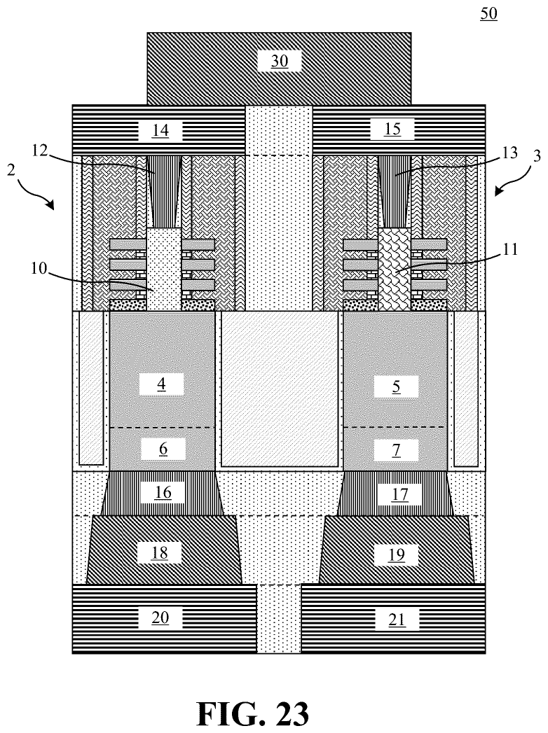

In an alternative substrate region arrangement, as depicted in FIG. 23, P+ substrate region 8 and N+ substrate region 9 are removed. In this implementation, as depicted, N− well substrate region 4 is connected to P+ device region 10 and P− well substrate region 5 is connected to N+ device region 11. In this arrangement, a relatively thinner substrate may be utilized which may assist in reducing a thickness of the semiconductor IC device 50. In contrast, in the embodiment depicted in FIG. 1, the diode junctions are entirely within the substrate which may achieve relatively better diode ideality and increased diode junction area in same footprint area.

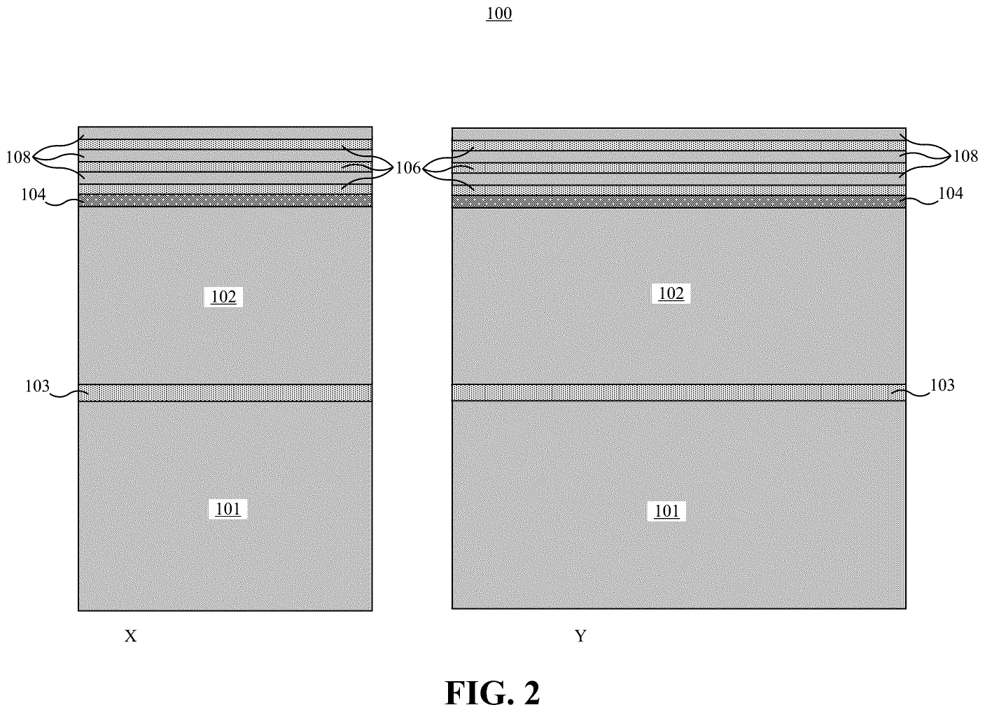

Turning now to a more detailed description of fabrication operations and resulting structures according to embodiments of the disclosure, FIGS. 2-21 depict a semiconductor IC device 100 device that includes, or is to include, an ESD protection device that uses a BSPDN after various fabrication operations. For ease of illustration, the fabrication operations depicted therein will be described in the context of forming elements of GAA FETs in a logic region, depicted in an X cross-section view, of the semiconductor IC device 100, in possible conjunction with forming elements of the ESD protection device in an ESD region, depicted in an Y cross-section view, of the semiconductor IC device 100.

Although the cross-sectional structural diagrams depicted in the drawings are two-dimensional, it is understood that the diagrams depicted represent three-dimensional devices. For clarity, the term “same region type” or the like is defined herein to be regions of the semiconductor IC device that share the same semiconductor dopants or impurities and/or charges and need not be in the same physical location.

FIG. 2 depicts cross-sectional views of the semiconductor IC device 100 after initial fabrication operations, in accordance with embodiments of the present disclosure. In the present fabrication stage, one or more nanolayers are formed upon a substrate.

The substrate may include a multilayered substrate that includes an upper substrate 102 and a lower substrate 101. An etch stop layer 103 may be located between the upper substrate 102 and the lower substrate 101. The etch stop layer 103 is generally formed of a material with etch selectivity to upper substrate 102 and/or lower substrate 101. Non-limiting examples of suitable materials for the upper substrate 102 and/or lower substrate 101 include Si (silicon), strained Si, SiC (silicon carbide), Ge (germanium), SiGe (silicon germanium), SiGe: C (silicon-germanium-carbon), Si alloys, Ge alloys, III-V materials (e.g., GaAs (gallium arsenide), InAs (indium arsenide), InP (indium phosphide), or aluminum arsenide (AlAs)), II-VI materials (e.g., CdSe (cadmium selenide), CdS (cadmium sulfide), CdTe (cadmium telluride), ZnO (zinc oxide), ZnSe (zinc selenide), ZnS (zinc sulfide), or ZnTe (zinc telluride)), or any combination thereof. Other non-limiting examples of semiconductor materials include III-V materials, for example, indium phosphide (InP), gallium arsenide (GaAs), aluminum arsenide (AlAs), or any combination thereof. The III-V materials can include at least one “III element,” such as aluminum (Al), boron (B), gallium (Ga), indium (In), and at least one “V element,” such as nitrogen (N), phosphorous (P), arsenic (As), antimony (Sb).

Nanolayers may be formed by initially fabricating a sacrificial nanolayer 104 upon substrate 102. Further nanolayers may be formed by fabricating an alternating series of sacrificial nanolayers 106, such as SiGe sacrificial nanolayers, and active nanolayers 108, such as Si nanolayers, upon the sacrificial nanolayer 104. The sacrificial nanolayers 106 can have Ge % ranging from 20% to 45%. In an implementation, the sacrificial nanolayer 104 may be epitaxially grown from the substrate 102 and the alternating active sacrificial nanolayer 106 and active nanolayer 108 may be formed by epitaxially growing one layer and then the next until the desired number and desired thicknesses of the layers are achieved. Any number of alternating nanolayers can be provided. Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

In some embodiments of the disclosure, the active nanolayers 108 are formed from Si and can include, for example, monocrystalline Si. The active nanolayers 108 can have a thickness of, for example, from about 4 to about 12 nm. In embodiments the sacrificial nanolayers 106 are formed from SiGe and the sacrificial nanolayers 106 can have a thickness of, for example, from about 4 to about 12 nm. The sacrificial nanolayers 106 can have Ge % ranging from 20% to 45%. The sacrificial nanolayer 104 may be formed by epitaxially growing a SiGe layer with high Ge %, ranging from 50% to 70%. In some embodiments, the sacrificial nanolayer 104 is formed of a material that is sufficiently different from the sacrificial nanolayers 106 and active nanolayers 108, such that the sacrificial nanolayer 104 can be selectively removed without also removing the sacrificial nanolayers 106 and active nanolayers 108, and/or vice versa. The sacrificial nanolayer 104 can have a thickness of, for example, from about 4 to about 15 nm.

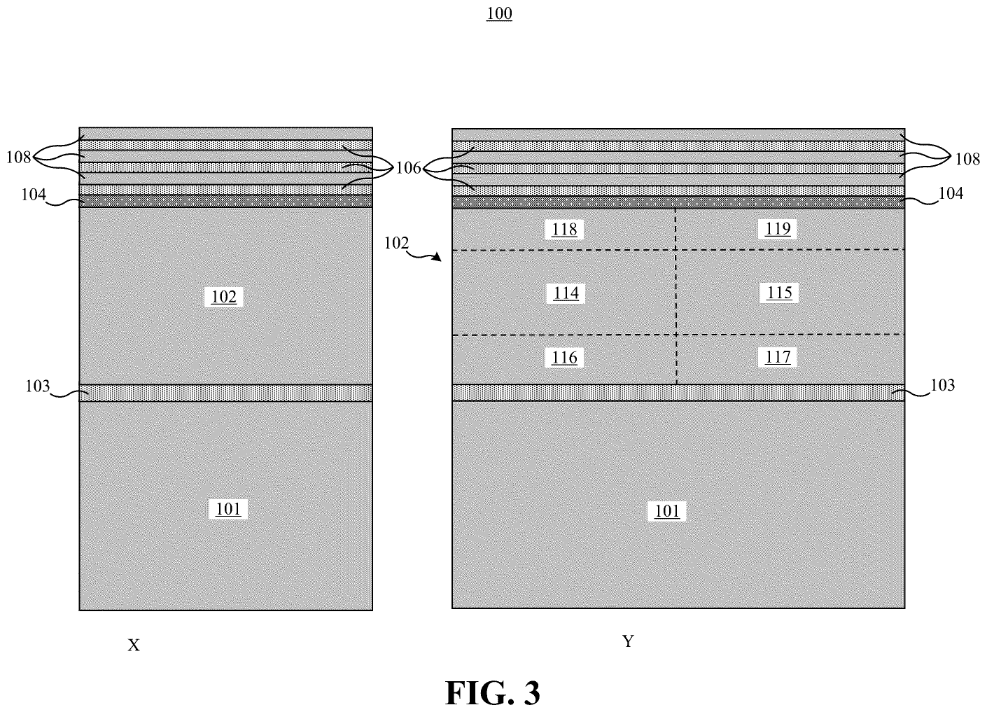

FIG. 3 depicts cross-sectional views of semiconductor IC device 100 shown after exemplary fabrication operation(s), in accordance with one or more embodiments. In the depicted fabrication stage, ions or dopants are added within the upper substrate 102 in the ESD region.

In semiconductor production, doping is the intentional introduction of impurities into an intrinsic semiconductor for the purpose of modulating its electrical, optical and/or structural properties. The doped material may be referred to as an extrinsic semiconductor.

Small numbers of dopant atoms can change the ability of a semiconductor to conduct electricity. When on the order of one dopant atom is added per 100 million atoms, the doping is said to be low or light. When many more dopant atoms are added, on the order of one per ten thousand atoms, the doping is referred to as high or heavy. A semiconductor doped to such high levels that it acts more like a conductor than a semiconductor is referred to as a degenerate semiconductor.

In general, increased doping leads to increased conductivity due to the higher concentration of carriers. Degenerate semiconductors have conductivity levels comparable to metals and are often used in integrated circuits as a replacement for metal. Often script plus and minus symbols are used to denote relative doping concentration in semiconductors. For example, N+ denotes an n-type semiconductor with a high, often degenerate, doping concentration. Similarly, P− would indicate a very lightly doped p-type material.

Ions or dopants are added within the upper substrate 102 to form a N− well substrate region 114, an N+ substrate region 116, a P+ substrate region 118, a P− well substrate region 115, a P+ substrate region 117, and/or N+ substrate region 119. To define these regions, selected areas of the semiconductor IC device 100 may be defined by photolithography and may be doped by exemplary doping techniques such as diffusion, ion implantation, or otherwise incorporating appropriate impurities, or the like. In an alternative implementation, the upper substrate 102 may be doped as depicted by the substrate of FIG. 23.

Typical dopant concentration of highly doped regions (e.g., N+ substrate region 116, P+ substrate region 117, P+ substrate region 118, and N+ substrate region 119, etc.) may be 1E19 to 1E21 cm−3. Typical dopant concentration of lightly doped regions (e.g., N− well substrate region 114, P− well substrate region 115, etc.) may be doped at 1e16 to 1E18 cm−3.

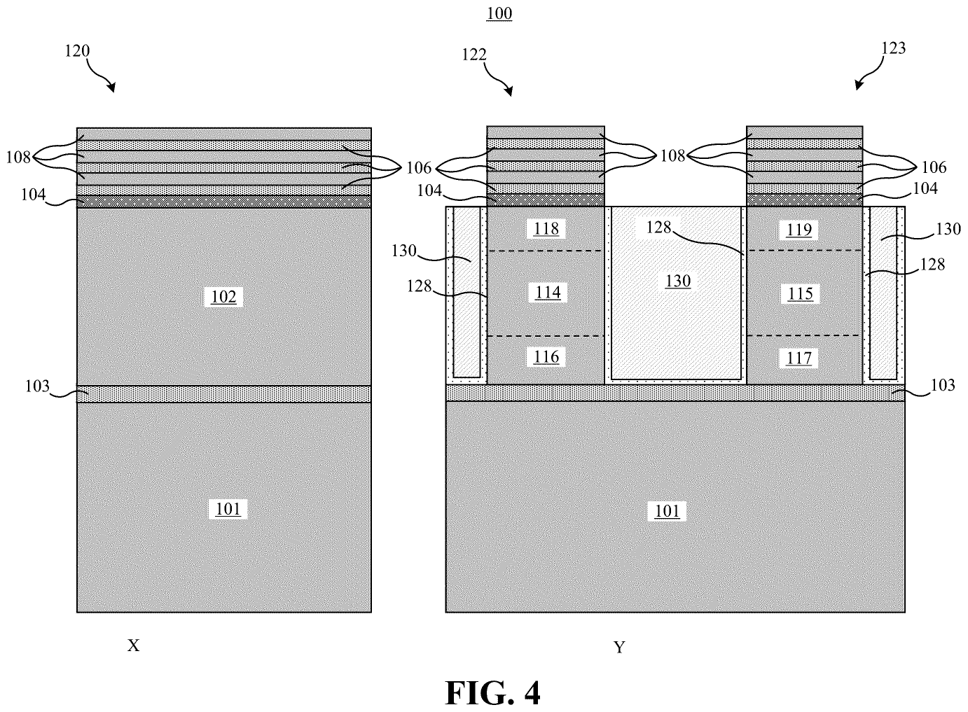

FIG. 4 depicts cross-sectional views of semiconductor IC device 100 shown after exemplary fabrication operation(s), in accordance with one or more embodiments. In the depicted fabrication stage, one or more nanolayer stack(s) 120 are patterned in the logic region and a nanosheet stack 122 and a nanosheet stack 123 are formed in the ESD region. Further in the present fabrication stage, shallow trench isolation (STI) region(s) may be formed within the upper substrate 102 next to nanolayer stacks 120, 122, and/or 123.

A mask layer (not shown) that may be used to pattern the nanolayers into nanolayer stacks 120, 122, and/or 123 may be initially formed upon the top nanolayer. The mask layer may be patterned by photolithography which resultantly exposes portions of the underlying top nanolayer while protecting other portions of the underlying nanolayers.

The nanolayer stacks 120, 122, and/or 123 may be patterned by removing respective undesired portion(s) or section(s) of the sacrificial nanolayer 104, sacrificial nanolayers 106, and active nanolayers 108 while retaining respective desired portions thereof. The removal of undesired portions of the sacrificial nanolayer 104, sacrificial nanolayers 106, and active nanolayers 108 can be accomplished using, for example, lithography and etch processes. The removal of such undesired portions may further remove undesired portions of upper substrate 102 down to the etch stop layer 103 that are adjacent to respective footprints of nanolayer stacks 120, 122, and/or 123. The desired portions of the sacrificial nanolayer 104, sacrificial nanolayers 106, and active nanolayers 108 may be protected by the patterned mask layer and resultingly form the nanolayer stacks 120, 122, and/or 123.

Further in the present fabrication stage, STI region(s) may be formed upon and/or within the recessed upper substrate 102 adjacent to respective footprints of nanolayer stacks 120, 122, and/or 123. For example, STI region(s) may be formed within the recessed upper substrate 102 adjacent to the nanolayer stacks 120 (into and/or out of the page), STI region(s) may be formed within the recessed upper substrate 102 adjacent to the nanolayer stacks 122, 123. In the embodiment depicted, a top surface of one or more STI region(s) may be coplanar with a top surface of upper substrate 102. STI region(s) may be formed by depositing STI liner 128 upon the etch stop layer 103 and upon the upper substrate adjacent to the footprint of nanolayer stacks 120, 122, and/or 123. Subsequently, STI region(s) may be further formed by depositing STI dielectric material 130 upon the STI liner 128. A STI liner 128 and/or STI dielectric material 130 etch back, recess, or the like, may occur to remove undesired or over formed STI liner 128 and/or STI dielectric material 130. The STI region(s) may electrically isolate or at least partially electrically separate components or features of neighboring devices, or the like.

For clarity, as depicted in the ESD region, side surfaces of the N− well substrate region 114, the N+ substrate region 116, and the P+ substrate region 118 may be bounded by respective one or more STI region(s). Further, front and rear surfaces of the N− well substrate region 114, the N+ substrate region 116, and the P+ substrate region 118 may be bounded by respective one or more STI region(s). Similarly, side surfaces of the P− well substrate region 115, the P+ substrate region 117, and the N+ substrate region 119 may be bounded by respective one or more STI region(s). Further, front and rear surfaces of the P-well substrate region 115, the P+ substrate region 117, and the N+ substrate region 119 may be bounded by respective one or more STI region(s).

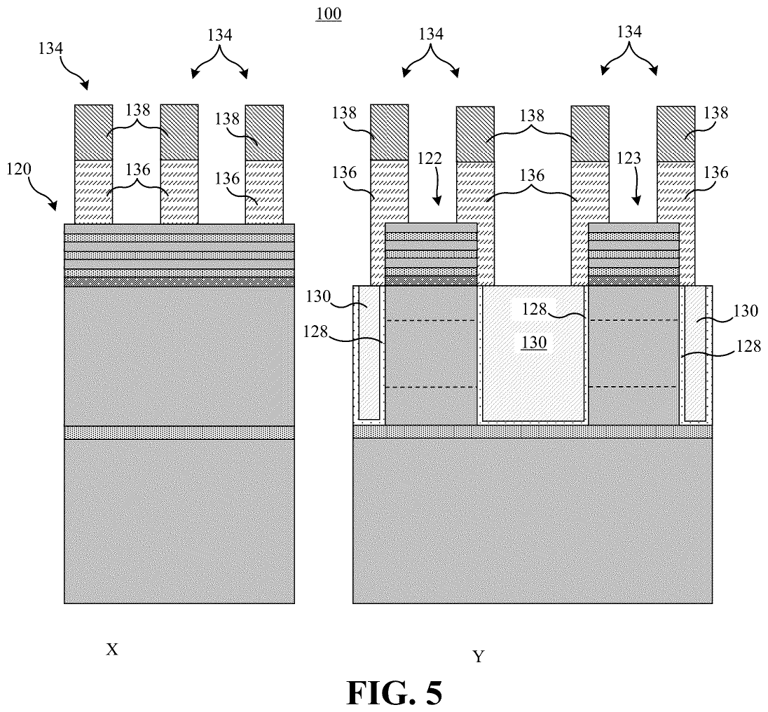

FIG. 5 depicts cross-sectional views of semiconductor IC device 100 shown after exemplary fabrication operation(s), in accordance with one or more embodiments. In the depicted fabrication stage, one or more sacrificial gate structures 134 are formed upon the STI region(s) and upon and around the nanolayer stacks 120, 122, and/or 123. Sacrificial gate structure(s) 134 may include a sacrificial gate liner (not shown), a sacrificial gate 136, and a sacrificial gate cap 138.

The sacrificial gate structure(s) 134 may be formed by depositing a sacrificial gate liner layer (e.g., a dielectric, oxide, or the like) upon STI regions and upon and around nanolayer stacks 120, 122, and/or 123. The sacrificial gate structure 134 may further be formed by subsequently depositing a sacrificial gate layer (e.g., amorphous silicon, or the like) upon the sacrificial gate liner layer. The thickness of the sacrificial gate layer may be greater than the height of the one or more nanolayer stacks 120, 122, and/or 123. The sacrificial gate structure 134 may further be formed by subsequently forming a gate cap layer upon the sacrificial gate layer. The gate cap layer may be formed by depositing a mask material, such as a hard mask material, such as silicon nitride, silicon oxide, combinations thereof, or the like. The gate cap layer may be composed of one or more layers of masking materials to protect the sacrificial gate layer and/or other underlying materials during subsequent processing of semiconductor IC device 100.

The sacrificial gate structure 134 may further be formed by patterning the gate cap layer, sacrificial gate layer, and sacrificial gate liner by, for example, using lithography and etch processes to remove undesired portions and retain desired portion(s), respectively. The retained desired portion(s) of the gate cap layer, sacrificial gate layer, and sacrificial gate liner may form the sacrificial gate liner (not shown), the sacrificial gate 136, and the sacrificial gate cap 138, respectively, of each of the one or more sacrificial gate structures 134.

One or more sacrificial gate structure 134 can be formed on targeted regions or areas of semiconductor IC device 100 within the logic region to define the length of one or more GAA FETs, one or more GAA FET channels, or the like, and to provide sacrificial material for yielding targeted GAA FET structure(s) in subsequent processing. According to an example, each sacrificial gate structure 134 within the logic region can have a height of between approximately 50 nm and approximately 200 nm, and a length of between approximately 10 nm and approximately 200 nm.

One or more sacrificial gate structure 134 within the ESD region can be formed upon respective front and rear sides (e.g., out of the front of the paper, out of the back of the paper) of nanolayer stacks 120, 122, and/or 123 as wells as respective side surfaces of nanolayer stacks 120, 122, and/or 123, as depicted.

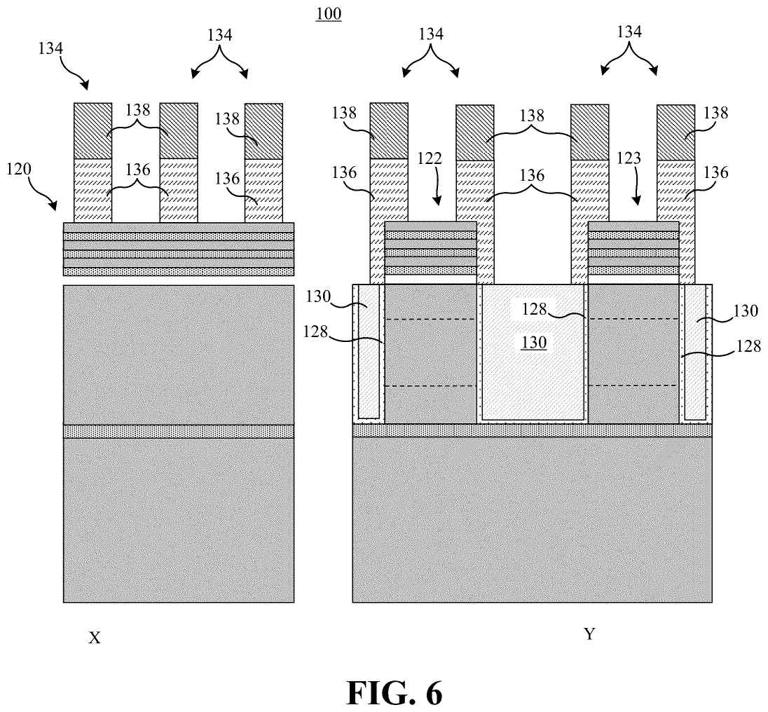

FIG. 6 depicts cross-sectional views of semiconductor IC device 100 shown after exemplary fabrication operation(s), in accordance with one or more embodiments. In the depicted fabrication stage, sacrificial nanolayer 104 may be selectively removed. The sacrificial nanolayer 104 may be the SiGe based layer with high Ge %, ranging from 50% to 70%, and/or material layer that is sufficiently different from the sacrificial nanolayers 106, active nanolayers 108, substrate 102, and/or sacrificial gate structures 134, such that the sacrificial nanolayer 104 can be selectively removed without also removing the other features. The sacrificial nanolayer 104 may be removed by a selective removal process, such as a selective etch.

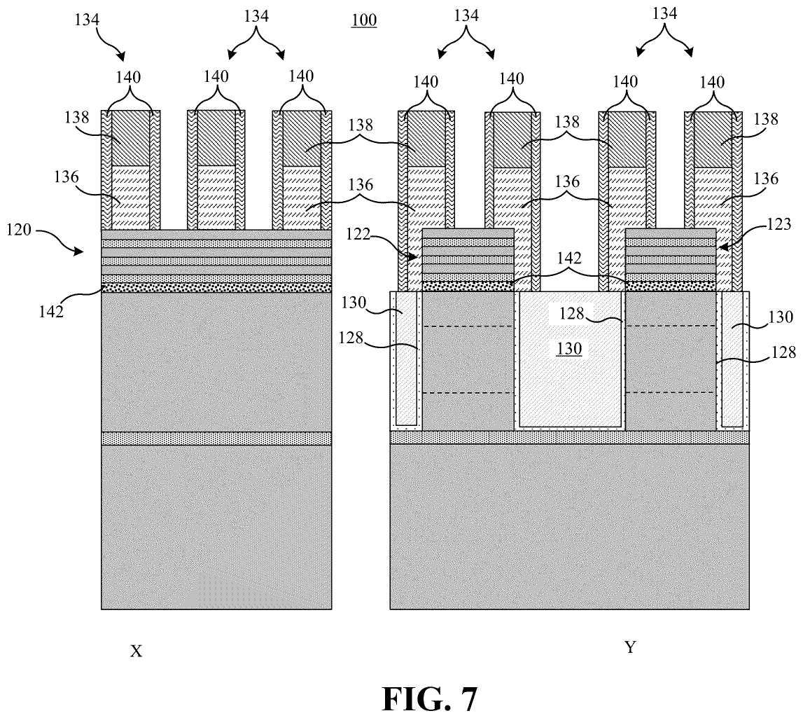

FIG. 7 depicts cross-sectional views of semiconductor IC device 100 shown after exemplary fabrication operation(s), in accordance with one or more embodiments. In the depicted fabrication stage, one or more bottom dielectric isolation(s) (BDI) 142 may be formed in place of the removed sacrificial nanolayer 104 and one or more spacer(s) 140 may be formed. The BDI(s) and spacer(s) 140 may be respectively formed upon substrate 102, may be formed upon STI region(s), may be formed upon and around nanolayer stacks 120, 122, and/or 123, and may be formed upon and around the one or more sacrificial gate structure(s) 134.

The BDI(s) 142 may be formed upon the upper substrate 102 in the logic region between the nanolayers of the nanolayer stack(s) 120 and upper substrate 102 and upon the topmost doped substrate region in the ESD region between the nanolayers of the nanolayer stacks 122, 123. The BDI(s) 142 may have a horizontal orientation, as depicted.

Spacer(s) 140 may be formed around each of the one or more sacrificial gate structures 134, may be formed upon at least a portion of the sidewalls of the one or more nanolayer stack 120, 122, 123, and may be formed upon the top surface of portion(s) of the STI regions. In one example, as depicted, spacers 140 and BDI(s) may be formed of relatively different dielectric materials, such as such as silicon nitride, SiBCN, SiNC, SiN, SiCO, SiNOC, or a combination thereof.

Spacer(s) 140 and BDI(s) 142 may be simultaneously formed by a deposition of a dielectric material, such as silicon nitride, SiBCN, SiNC, SiN, SiCO, SiNOC, or a combination thereof, or the like, in place of the removed sacrificial nanolayers 107. Excess, undesired, and/or exposed dielectric material may be subsequently removed by a substrative removal technique, such as an etch.

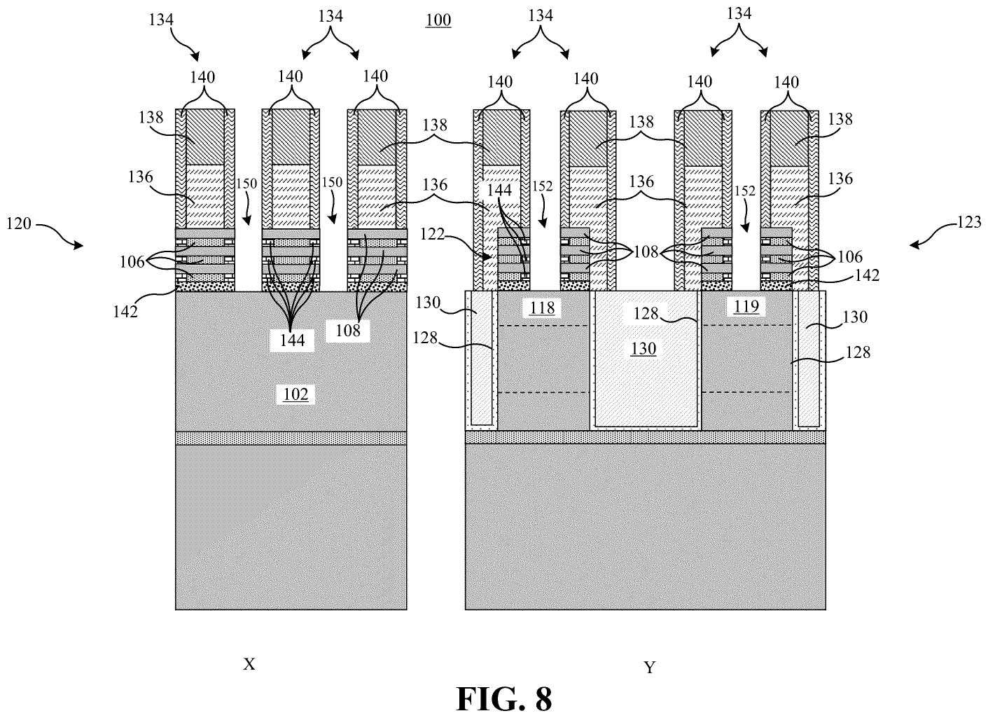

FIG. 8 depicts cross-sectional views of semiconductor IC device 100 shown after exemplary fabrication operation(s), in accordance with one or more embodiments. In the depicted fabrication stage, source/drain (S/D) recesses 150 are formed within the nanolayer stack 120 between spacers 140 associated with neighboring sacrificial gate structures 134 in the logic region and ESD recesses 152 are formed within the nanolayer stacks 122, 123 between spacers 140 associated with neighboring sacrificial gate structures 134 in the ESD region. Further in the depicted fabrication stage, sacrificial nanolayers 106 within nanolayer stacks 120, 122, and/or 123 may be indented, thereby forming an indent void, and an inner spacer 144 may be formed within a respective indent void.

In the logic region, the one or more S/D recesses 150 may be formed between sacrificial gate structures 134 by removing sacrificial nanolayer(s) 106, by removing active nanolayer(s) 108, and by removing sacrificial nanolayer 104 that are between spacer(s) 140 of adjacent or neighboring sacrificial gate structures 134. The one or more S/D recesses 150 may be formed to a depth so as to stop at the upper substrate 102. The one or more S/D recesses 150 may be formed by removing undesired portions of the nanolayers, removing the portions of the nanolayers that are that are not protected by sacrificial gate structure 134 and/or by spacer(s) 140, or the like. These undesired portions of the nanolayers may be removed by etching or other subtractive removal techniques. The top surface STI region(s) (STI dielectric 130, etc.) may be used as an etch stop. The retained one or more portions of one or more nanolayer stacks 120 may be such portions thereof that were protected generally below a sacrificial gate structure 134 and/or by the associated spacer(s) 140.

In the ESD region, the ESD recesses 152 may be formed between sacrificial gate structures 134 by removing sacrificial nanolayer(s) 106, by removing active nanolayer(s) 108, and by removing sacrificial nanolayer 104 that are between spacer(s) 140 of adjacent or neighboring sacrificial gate structures 134. The ESD recesses 150 may be formed to a depth so as to stop at a respective topmost doped substrate region of upper substrate 102 (e.g., P+ substrate region 118, N+ substrate region 119, etc.). The ESD recesses 150 may be formed by removing undesired portions of the nanolayers, removing the portions of the nanolayers that are that are not protected by sacrificial gate structure 134 and/or by spacer(s) 140, or the like. These undesired portions of the nanolayers may be removed by etching or other subtractive removal techniques. The top surface STI region(s) (STI dielectric 130, etc.) may be used as an etch stop. The retained one or more portions of one or more nanolayer stacks 122, 123 may be such portions thereof that were protected generally below a sacrificial gate structure 134 and/or by the associated spacer(s) 140.

The semiconductor IC device 100 may be subsequently subjected to a directional reactive ion etch (RIE) process, which can remove or indent portions of the sacrificial nanolayers 106 that are not covered by the sacrificial gate 136 and/or that are under the spacer(s) 140. The RIE can use a boron-based chemistry or a chlorine-based chemistry, for example, which selectively recesses the exposed portions sacrificial nanolayers 106 (e.g., those portions of sacrificial nanolayers 106 generally below spacer(s) 140, etc.) without significantly removing the active semiconductor nanolayers 108.

Subsequently, a respective inner spacer 144 may be deposited in the recess or indent that was previously formed into the sacrificial nanolayers 106. In certain embodiments, after the formation of the inner spacers 144, an isotropic etch process is performed to create outer vertical edges to the inner spacers 144 that align with outer vertical edges of the active semiconductor nanolayers 108. In certain embodiments, the material of the inner spacer 144 is a dielectric material such as SiN, SiO, SiBCN, SiOCN, SiCO, etc.

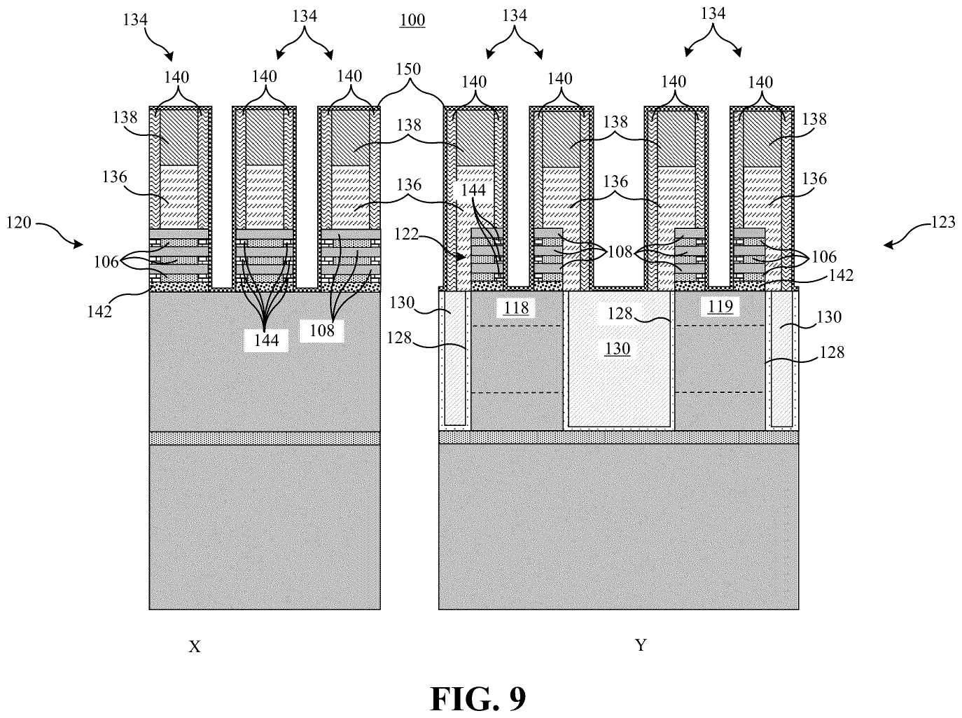

FIG. 9 depicts cross-sectional views of semiconductor IC device 100 shown after exemplary fabrication operation(s), in accordance with one or more embodiments. In the depicted fabrication stage, a blanket liner 150 is formed.

The blanket liner 150 may be formed by depositing a dielectric material, such as, for example, porous silicates, carbon doped oxides, silicon dioxides, silicon nitrides, silicon oxynitrides, or other dielectric materials. Any appropriate deposition technique for forming the blanket liner 150 can be utilized. The blanket liner 150 can be formed using, for example, CVD, PECVD, ALD, flowable CVD, spin-on dielectrics, or PVD.

As depicted in the logic region, the blanket liner 150 may be deposited upon spacer(s) 140, upon sacrificial gate cap(s) 138, upon active semiconductor nanolayers 108, upon inner spacers 144, upon BDI(s) 142, upon substrate 102, upon STI region(s), or the like. As depicted in the ESD region, the blanket liner 150 may be deposited upon spacer(s) 140, upon sacrificial gate cap(s) 138, upon active semiconductor nanolayers 108, upon inner spacers 144, upon BDI(s) 142, upon the topmost doped substrate regions (e.g., P+ substrate region 118, N+ substrate region 119, etc.), upon STI region(s), or the like.

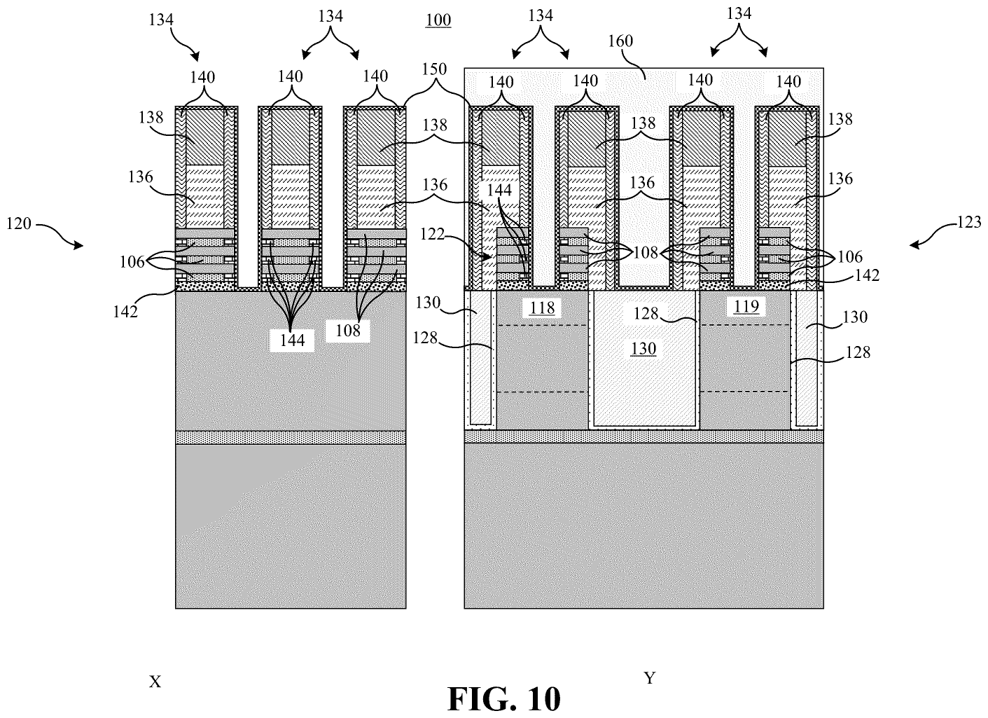

FIG. 10 depicts cross-sectional views of semiconductor IC device 100 shown after exemplary fabrication operation(s), in accordance with one or more embodiments. In the depicted fabrication stage, a mask 160 is formed over the ESD region. The mask 160 may consist of a dielectric material, organic planarization layer (OPL) material, mask material, or the like, and may be formed by depositing a blanket mask material upon the blanket liner 150. A portion of the blanket mask layer that is located in the logic region may be removed, thereby exposing respective portions of the blanket liner 150 therewithin. In other words, undesired portion(s) of the blanket mask layer may be removed by, for example, lithography and etching techniques, while desired portion(s) of blanket mask layer are retained and may generally cover and protect the underlying EDS region.

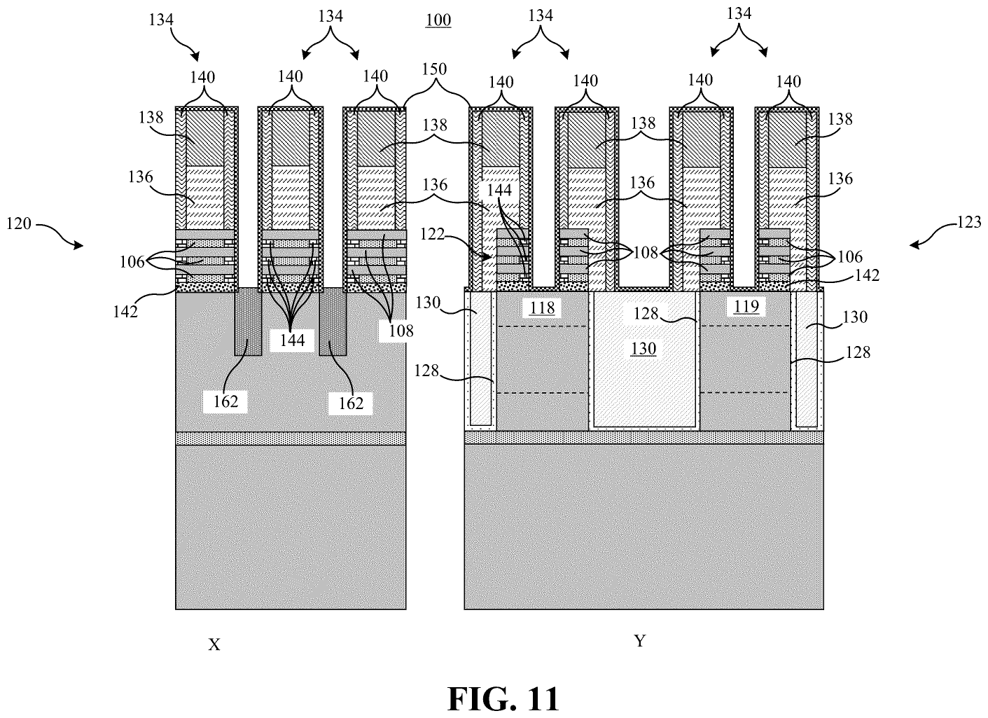

FIG. 11 depicts cross-sectional views of semiconductor IC device 100 shown after exemplary fabrication operation(s), in accordance with one or more embodiments. In the depicted fabrication stage, one or more backside contact placeholder(s) 162 are formed within upper substrate 102. Further in the depicted fabrication stage, mask 160 is removed.

The one or more backside contact placeholder(s) 162 may be formed by initially forming one or more backside contact placeholder(s) cavities within the substrate generally between adjacent sacrificial gate structures 134 and underneath respective S/D locations in the logic region. For example, the one or more backside contact placeholder(s) cavities may be formed by a subtractive removal technique, such as an etch, that removes associated portion(s) of the blanket liner 150 and substrate 102 within logic region. The etch may be timed or otherwise controlled to stop the removal of the substrate 102 within logic region such that the depth or bottom of the one or more backside contact placeholder(s) 162 is above the etch stop layer 103.

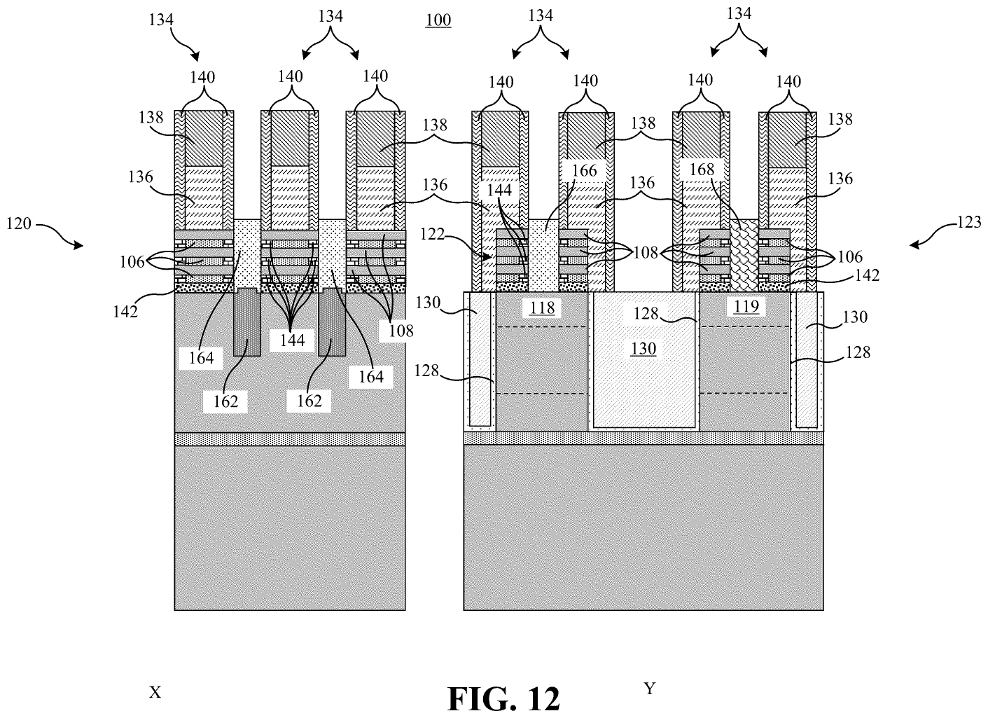

The one or more backside contact placeholder(s) 162 may be further formed by epitaxially growing a sacrificial epitaxial material from exposed substrate 102 surface(s) within the one or more backside contact placeholder(s) cavities. In some embodiments, epitaxial growth and/or deposition processes may be selective to forming on the semiconductor surfaces of substrate 102, and may not deposit material on dielectric surfaces, such as silicon dioxide or silicon nitride surfaces. In some embodiments, the one or more backside contact placeholder(s) 162 epitaxial growth may overgrow above the top surface of substrate 102. In an example, the sacrificial epitaxial material of the one or more backside contact placeholder(s) 162 may be chosen to be etch selective to the material of the S/D region(s) 164, depicted in FIG. 12, the material of substrate 102, or the like. In an example, the one or more backside contact placeholder(s) 162 may be bounded on each side by the substrate, as depicted, and may be bounded on the front and rear by respective one or more STI regions.

After formation of the one or more backside contact placeholder(s) 162, the mask 160 may be removed by subtractive removal techniques such as etching, OPL ashing, or the like. Specifically, the mask 160 material within the ESD region and upon blanket liner 150 may be removed and may effectively expose the blanket liner 150 thereunder.

FIG. 12 depicts cross-sectional views of semiconductor IC device 100 shown after exemplary fabrication operation(s), in accordance with one or more embodiments. In the depicted fabrication stage, a S/D region 164 is formed upon a respective backside contact placeholder 162 within the logic region. Further in the depicted fabrication stage, ESD region 166 and ESD region 168 are formed within the ESD region.

The S/D region 164 forms either a source or a drain, respectively, to each associated or connected nanosheet FET (i.e., those FETs in which the source or drain is connected to the active semiconductor nanolayers 108 channels) in the logic region. ESD region 166 and ESD region 168 forms a respective ESD region (e.g., P+ device region 10, N+ device region 11, or the like) in the ESD region.

S/D regions 164, ESD region 166, and ESD region 168 may be epitaxially grown or formed. The S/D regions 164 may be formed by epitaxially growing epitaxial material upon a respective backside contact placeholder 162 within the logic region between neighboring nanosheet FETs. ESD region 166 and ESD region 168 may be formed by epitaxially growing epitaxial material upon the topmost doped substrate region of upper substrate 102 (e.g., P+ substrate region 118, N+ substrate region 119, etc.) between neighboring sacrificial gate structures 134.

In some examples, S/D regions 164, ESD region 166, and ESD region 168 are formed by in-situ doped epitaxial growth. In some embodiments, the S/D regions 164, ESD region 166, and ESD region 168 epitaxial growth may overgrow above the upper surface of the topmost active semiconductor nanolayer 108 within nanolayer stacks 120, 122, and/or 123.

Suitable n-type dopants include but are not limited to phosphorous (P), and suitable p-type dopants include but are not limited to boron (B). The use of an in-situ doping process is merely an example. For instance, one may instead employ an ex-situ process to introduce dopants into the source and drains. Other doping techniques can be used to incorporate dopants in the bottom source/drain region. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In preferred embodiments, the S/D epitaxial growth conditions that promote in-situ Boron doped SiGe for p-type transistor and phosphorus or arsenic doped silicon or Si: C for n-type transistors. The doping concentration in the S/D regions 164 can be in the range of 1×1019 cm-3 to 2×1021 cm−3, or preferably between 2×1020 cm−3 to 7×1020 cm−3.

In an example, ESD region 166 is a p-type semiconductor material and can be highly doped with a doping concentration in the range of 1×1019 cm−3 to 2×1021 cm−3, or preferably between 2×1020 cm−3 to 7×1020 cm−3.

Similarly, ESD region 168 is a n-type semiconductor material and can be highly doped and have a doping concentration in the range of 1×1019 cm−3 to 2×1021 cm−3, or preferably between 2×1020 cm−3 to 7×1020 cm−3.

In certain implementations, the S/D regions 164, ESD region 166, and ESD region 168 may be partially recessed such that an upper portion of the S/D regions 164, ESD region 166, and/or ESD region 168 are removed. For example, the upper portion of the S/D regions 164, ESD region 166, and/or ESD region 168 may be etched or otherwise removed. The etch may be timed or otherwise controlled to stop the removal of S/D regions 164, ESD region 166, and B/or ESD region 168 such that the top surface(s) thereof are above the upper surface of the topmost active semiconductor layer 108.

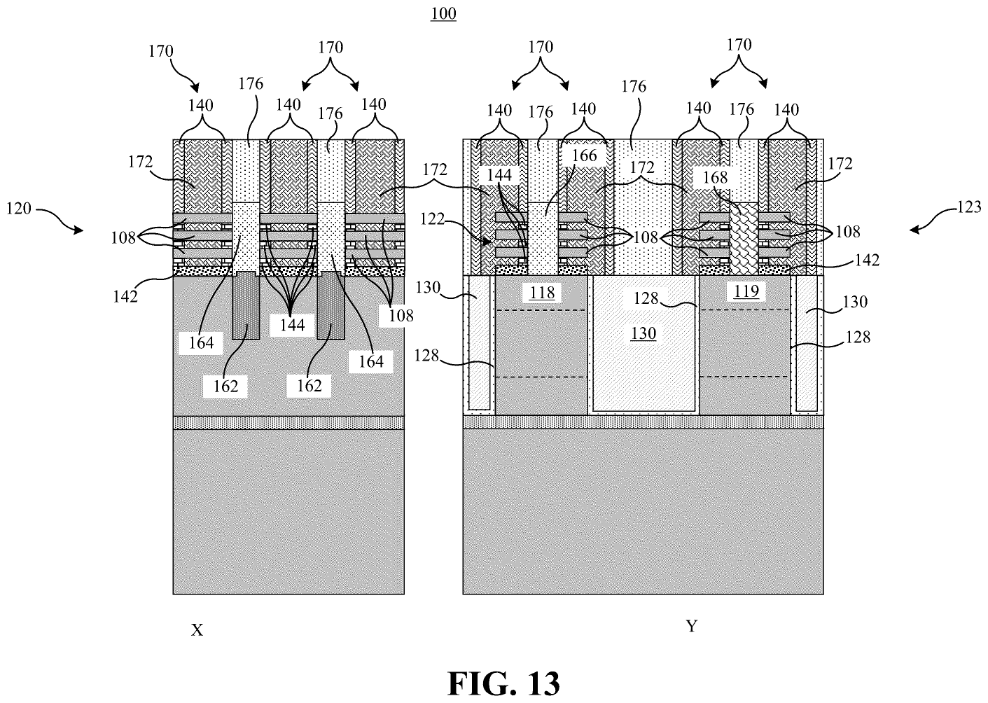

FIG. 13 depicts cross-sectional views of semiconductor IC device 100 shown after exemplary fabrication operation(s), in accordance with one or more embodiments. In the depicted fabrication stage, ILD 176 is formed upon S/D regions 164, ESD region 166, ESD region 168, and/or upon STI regions. Further in the depicted fabrication stage, sacrificial gate structures 134 are removed, the sacrificial nanolayers 106 are removed, and a replacement gate structure 170 is formed.

ILD 176 may be formed upon and around the S/D regions 164, upon STI region(s), upon spacer(s) 140, or the like, within the logic region and within the ESD region. The ILD 176 may be formed by depositing a dielectric material upon S/D region 164, upon insulator layer 104, and upon spacer 120. The ILD 176 can be any suitable material, such as, for example, porous silicates, carbon doped oxides, silicon dioxides, silicon nitrides, silicon oxynitrides, or other dielectric materials. In an example, the ILD 176 may be formed to a thickness so that the top surface of the ILD 176 is above the semiconductor IC device 100 and subsequently etched back such that the top surface of the ILD 176 is coplanar with a top surface of the gate hard mask 118 and/or a top surface of spacer(s) 140. In another example, a planarization process, such as a chemical mechanical polish (CMP), may be performed to create a planar upper surface for the semiconductor IC device 100. In this example, the CMP may be performed to a depth to expose the sacrificial gate structure 134 (e.g., the sacrificial gate cap 138 may be removed).

Further in the depicted fabrication stage, the sacrificial gate structure(s) 134 are removed and a respective replacement gate structure 170 is formed in place of a respective sacrificial gate structure 134 within the logic region and within the ESD region. The sacrificial gate structures 134 may be removed by removing associated portions of sacrificial gate cap 138 (if not already removed), sacrificial gate 136, sacrificial gate oxide (if present), and the sacrificial nanolayers 106 by a subtractive removal technique, such as one or more of etches. For example, removal of these features may be accomplished by an etching process which may include a dry etching process such as RIE, plasma etching, ion etching or laser ablation. The etching can further include a wet chemical etching process(es).

After the removal of sacrificial nanolayers 106, void spaces between the active semiconductor nanolayers 108 and/or BDI 142 are formed. It should be appreciated that during the removal of the sacrificial gate 136, the sacrificial oxide layer, the sacrificial nanolayers 106, and/or the like, appropriate etchants are used that do not significantly remove material of active semiconductor nanolayers 108, substrate 102, inner spacers 144, BDI 142, spacers 140, or the like. The dry and wet etching processes can have etching parameters that can be tuned, such as etchants used, etching temperature, etching solution concentration, etching pressure, source power, RF bias voltage, RF bias power, etchant flow rate, and other suitable parameters. Dry etching processes can include a biased plasma etching process that uses a chlorine-based chemistry. Other dry etchant gasses can include Tetrafluoromethane (CF4), nitrogen trifluoride (NF3), sulfur hexafluoride (SF6), and helium (He), and Chlorine trifluoride (CIF3). Dry etching can also be performed anisotropically using such mechanisms as DRIE (deep reactive-ion etching). Chemical vapor etching can be used as a selective etching method, and the etching gas can include hydrogen chloride (HCl), Tetrafluoromethane (CF4), and gas mixture with hydrogen (H2). Chemical vapor etching can be performed by CVD with suitable pressure and temperature.

The replacement gate structure 170 may be formed by initially forming an interfacial layer (not shown) on the interior surfaces of the spacer(s) 140, on the interior surfaces of the active semiconductor nanolayers 108, on the inner spacers 140, on the BDI 142, on the STI region(s), or the like. A high-K layer (not shown) may be formed to cover the surfaces of exposed surfaces of the interfacial layer. The high-layer can be deposited by any suitable techniques, such as ALD, CVD, metal-organic CVD (MOCVD), physical vapor deposition (PVD), thermal oxidation, combinations thereof, or other suitable techniques. A high-K material is a material with a higher dielectric constant than that of SiO₂, and can include e.g., LaO, AlO, ZrO, TiO, Ta2O5, Y2O3, SrTiO3 (STO), BaTiO3 (BTO), BaZrO, HfZrO, HfLaO, HfSiO, LaSiO, AlSiO, HfTaO, HfTiO, BaSrTiO3 (BST), Al₂O₃, Si3N4, oxynitrides (SiON), or other suitable materials. The high-k layer can include a single layer or multiple layers, such as metal layer, liner layer, wetting layer, and adhesion layer. In other embodiments, the high-K layer can include, e.g., Ti, Ag. Al, TiAIN, TaC. TaCN, TaSiN, Mn, Zr, TiN, TaN, Ru, Mo, Al, WN, Cu, W, or any suitable materials.

Replacement gate structure 170 may be further formed by depositing a work function (WF) gate (not shown) upon the high-k layer. The WF gate can be comprised of metals, such as, e.g., copper (Cu), cobalt (Co), aluminum (Al), platinum (Pt), gold (Au), titanium (Ti), nitride (N) or any combination thereof. The metal can be deposited by a suitable deposition process, for example, chemical vapor deposition (CVD), plasma enhanced chemical vapor deposition (PECVD), physical vapor deposition (PVD), plating, thermal or e-beamF evaporation, or sputtering. In general, the work function (WF) gate sets the threshold voltage (Vt) of the transistors associated with the active semiconductor nanolayers 108 within the logic region. The high-κ layer can separate the WF gate and the active semiconductor nanolayers 108. The WF gate may be formed to a thickness to generally fill the gaps or voids between active semiconductor nanolayers 108.

Replacement gate structure 170 may be further formed by depositing a conductive fill gate 172 upon the WF gate. The conductive fill gate 172 can be comprised of metals, such as but not limited to, e.g., tungsten, aluminum, ruthenium, rhodium, cobalt, copper, tantalum, titanium, carbon nanowire materials including graphene, or the like. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. After the replacement gate structure 170 formation, the top surface of the semiconductor IC device 100 may be planarized by a planarization technique such as a CMP.

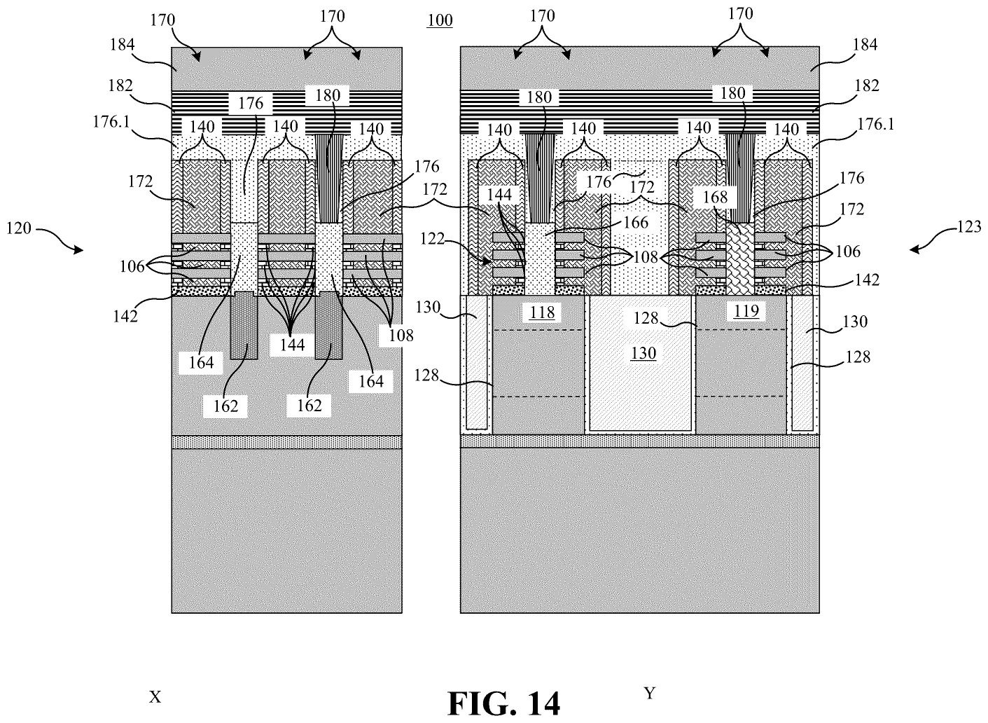

FIG. 14 depicts cross-sectional views of semiconductor IC device 100 shown after exemplary fabrication operation(s), in accordance with one or more embodiments. In the depicted fabrication stage, a ILD 176.1 is formed, a respective frontside contact 180 is formed upon one or more S/D regions 164, a respective frontside contact 180 is formed upon ESD region 166, and a respective frontside contact 180 is formed upon ESD region 168. Further in the depicted fabrication stage, frontside BEOL structure(s) 182 are formed, and a carrier wafer is bonded thereto.

The ILD 176.1 may be formed upon the top surface of ILD 176, upon the top surface of spacer(s) 140, upon the top surface of replacement gate structure(s) 170, and/or the like. The ILD 176.1 may be formed by depositing a dielectric material, such as, for example, porous silicates, carbon doped oxides, silicon dioxides, silicon nitrides, silicon oxynitrides, or other dielectric materials. Any known manner of forming the ILD 176.1 can be utilized. The ILD 176.1 can be formed using, for example, CVD, PECVD, ALD, flowable CVD, spin-on dielectrics, or PVD. The ILD 176.1 may be the same or different material relative to ILD 176.

Subsequently, front-side contact openings (not shown) are formed within ILD 176.1. The formation of front-side contact openings may include etching the ILD 176.1 to form the opening. A respective opening may expose at least a portion of S/D region 164, at least a portion of ESD region 166, or at least a portion of ESD region 168. Frontside contacts 180 may be formed by depositing conductive material within the front-side contact openings. The formation of the frontside contacts 180 may include forming a blanket conductive barrier layer extending into the front-side contact openings, depositing a metal or conductive material over the blanket conductive barrier layer, and performing a planarization process, such as a CMP process or a mechanical grinding process, to remove excess portions of the conductive barrier layer and the conductive material. Frontside contacts 180 may consist of a liner formed of Ni, NiPt, Ti, TiN, TaN, etc. and a conductive fill thereupon, such as Al, Ru, W, Co, Cu, etc. In some implementations, the formation of frontside contacts 180 may be a part of middle of the line (MOL) fabrication processes.

A respective frontside contact 180 may contact or otherwise meld to the exposed portion of the S/D region 164, of the ESD region 166, and of the ESD region 168. The respective frontside contact 180 located in the logic region, as depicted, may contact or otherwise meld to the exposed portion of the S/D region 164 and provide power potential (VDD, VSS, or the like) thereto. In the logic region, another respective frontside contact (not shown) may contact otherwise meld to the replacement gate structure. This gate contact may be further connected to a signal line and electrically carry a functional or logical potential or signal that is to change or is otherwise dynamic over time. Such functional or logical potential or signal may determine whether the associated transistor is on or off.

Frontside BEOL structure(s) 182 include metallization levels, associated metallization dielectric or passivation layers, vertical vias that connect the metallization feature(s) within the metallization levels with an underlying device or structure, and/or conductive I/O pads, or the like. Frontside BEOL structure(s) 182 include a respective same or different signal line or wiring line, such as a conductive wire, conductive trace, or the like, that is formed over frontside contacts 180 making electrical contact therewith. A signal line is defined herein as a conductive wiring feature that is configured to electrically carry a functional or logical potential or signal that is to change or is otherwise dynamic over time. The frontside BEOL structure(s) 182 that are connected to S/D region 164 through frontside contact 180 in the logic region may be one or more signal lines.

In some examples, there may be five metal levels M0-M4 within frontside BEOL structure(s) 182. In some examples, there may be more than ten metal levels M0-Mx within BEOL structure(s) 182. In some examples, frontside contact 180 may contact and connect the respective S/D region 164, ESD region 166, or ESD region 168 to a via, trace, signal line, power plane, power line, or the like located within the lowest BEOL metal level M0. Generally, the frontside BEOL structure(s) 182 are located on the frontside of the semiconductor IC device 102.

Upon completion of the frontside BEOL structure(s) 182, carrier wafer 184 may be bonded or otherwise attached to the top surface of BEOL structure(s) 182, as depicted. Carrier wafer 164 may be attached to semiconductor device 100 by a carrier bonding technique.

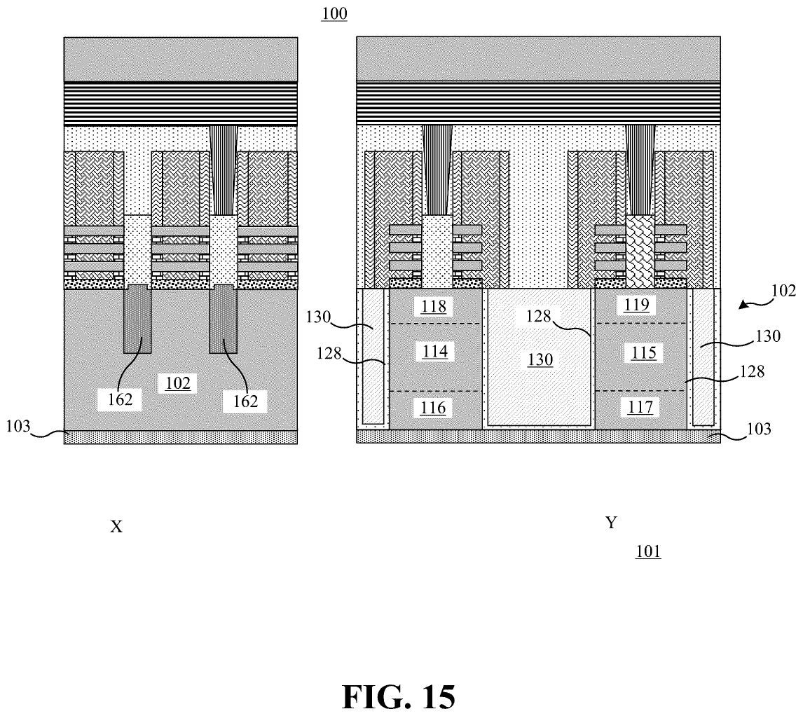

FIG. 15 depicts cross-sectional views of semiconductor IC device 100 shown after exemplary fabrication operation(s), in accordance with one or more embodiments. In the depicted fabrication stage, semiconductor IC device 100 is flipped (not shown) and lower substrate 101 is removed. The lower substrate 101 may be removed by any removal technique, such as a combination of wafer grinding, CMP, dry and wet etch. In the example depicted, lower substrate 101 is removed by an etch that utilizes etch stop layer 103 as the etch stop. In this example, removal of lower substrate 101 exposes the bottom surface of etch stop layer 103.

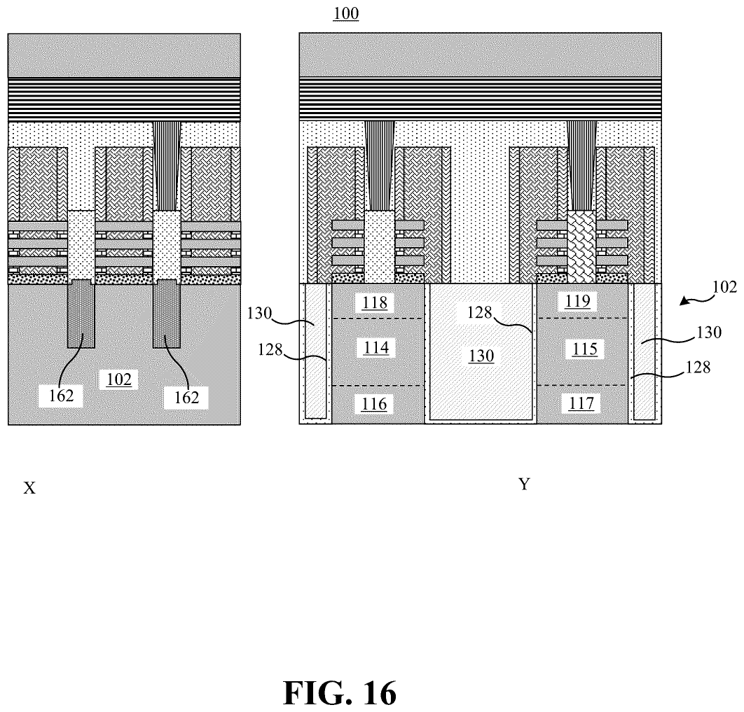

FIG. 16 depicts cross-sectional views of semiconductor IC device 100 shown after exemplary fabrication operation(s), in accordance with one or more embodiments. In the depicted fabrication stage, etch stop layer 103 is removed. The etch stop layer 103 may be removed by a subtractive removal technique such as a CMP, dry and/or wet etch. Upon removal of the etch stop layer 103, the bottom surface (as depicted) of the N+ substrate region 116, the bottom surface (as depicted) P+ substrate region 117 is exposed, and/or the bottom surface (as depicted) of STI region(s) are exposed.

In an alternative example, that may essentially combine the fabrication stages depicted in FIG. 15 and in FIG. 16, semiconductor IC device 100 may be flipped (not shown) the bottom surface (as depicted) of the N+ substrate region 116, the bottom surface (as depicted) P+ substrate region 117 is exposed, and/or the bottom surface (as depicted) of STI region(s) are exposed. That is, the lower substrate 101 and etch stop layer 103 (if present) may be removed by a removal technique, such as a combination of wafer grinding, CMP, dry and wet etch.

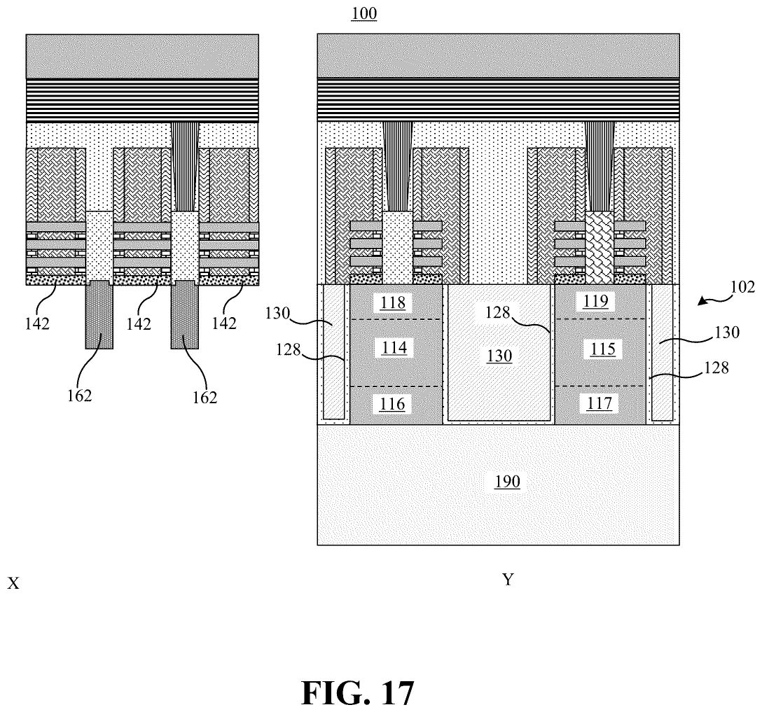

FIG. 17 depicts cross-sectional views of semiconductor IC device 100 shown after exemplary fabrication operation(s), in accordance with one or more embodiments. In the depicted fabrication stage, ESD region is protected by forming a mask 190 thereupon and the upper substrate 102 within the logic region is removed.

The mask 190 may be formed by depositing a blanket dielectric material or other mask material upon upper substrate 102 and upon STI regions within both the logic region and the ESD region. Using lithography and etching techniques the blanket layer located in the ESD region may be protected and the blanket layer located in the logic region may be exposed and removed. The remaining portions of the blanket layer may form the mask 190 within the ESD region. In other examples, the mask 190 may be formed directly, selectively, or, in other words, only within the ESD region.

The mask 190 can be any suitable material, such as, for example, porous silicates, oxides, nitrides, silicon oxynitrides, OPL, or other dielectric materials. Any known manner of forming the mask 190 can be utilized. The mask 190 can be formed using, for example, CVD, PECVD, ALD, flowable CVD, spin-on dielectrics, PVD, or the like.

Using the mask 190 to protect the ESD region, the upper substrate 102 within the logic region is removed by an appropriate substrative removal technique, such as an etch, that removes associated portion(s) substrate 102 within logic region. The etch may be timed or otherwise controlled to remove the material of substrate 102 within logic region and retain or otherwise expose the backside contact placeholder(s) 162 and BDI(s) 142, or the like. Subsequently, the mask 190 may be removed from the ESD region by an etch, OPL ash, or the like.

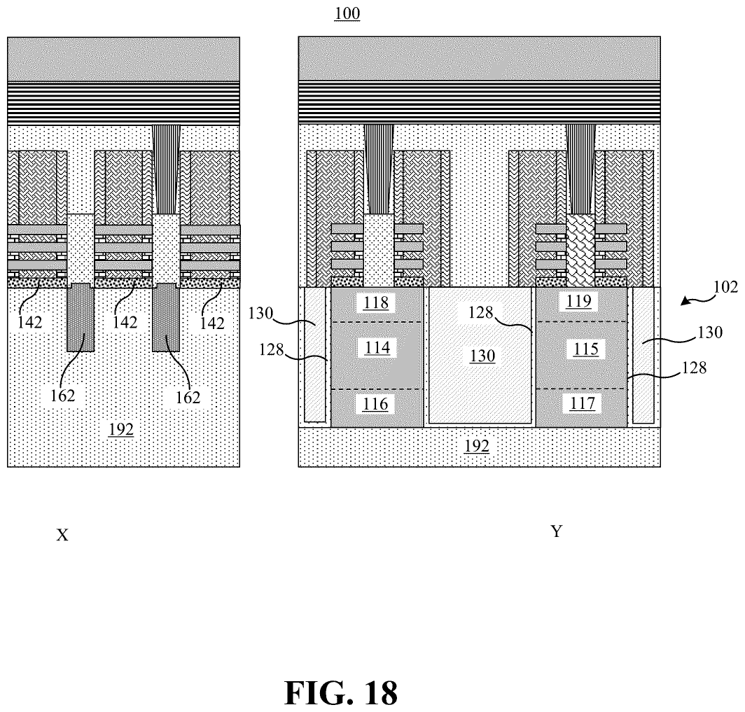

FIG. 18 depicts cross-sectional views of semiconductor IC device 100 shown after exemplary fabrication operation(s), in accordance with one or more embodiments. In the depicted fabrication stage, ILD 192 is formed within the logic region and within the ESD region. The ILD 192 may be formed upon the bottom surfaces (as depicted) of BDI(s) 142, upon and around the backside contact placeholder(s) 162, upon the bottom surfaces (as depicted) of STI region(s), upon the bottom surface (as depicted) of N+ substrate region 116, and upon the bottom surface (as depicted) of P+ substrate region 117. The ILD 192 may be formed by depositing a dielectric material, such as, for example, porous silicates, carbon doped oxides, silicon dioxides, silicon nitrides, silicon oxynitrides, or other dielectric materials. Any appropriate deposition technique for forming the ILD 192 can be utilized. The ILD 192 can be formed using, for example, CVD, PECVD, ALD, flowable CVD, spin-on dielectrics, or PVD.

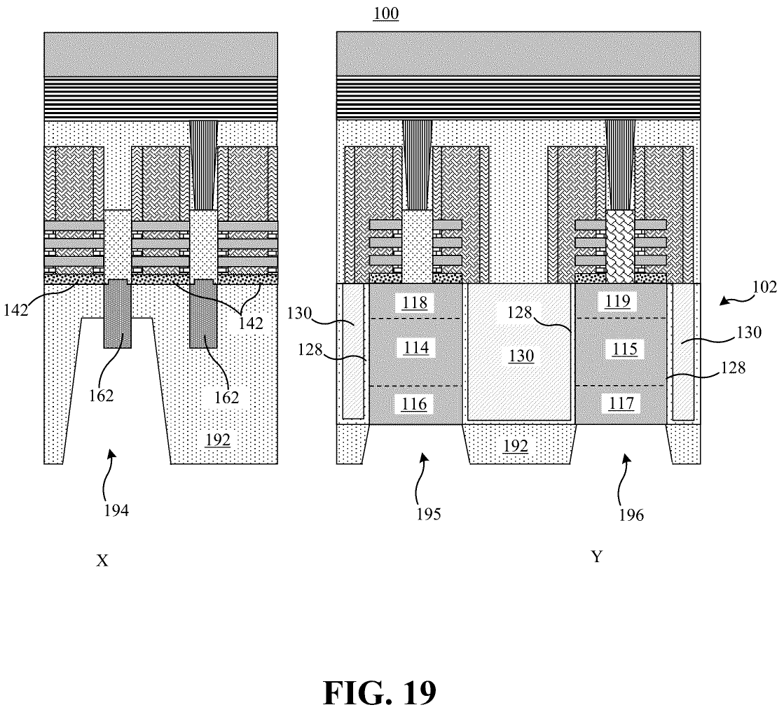

FIG. 19 depicts cross-sectional views of semiconductor IC device 100 shown after exemplary fabrication operation(s), in accordance with one or more embodiments. In the depicted fabrication stage, a backside contact opening 194 may be formed within the logic region, backside contact opening 195 may be formed within the ESD region, and backside contact opening 196 may be formed within the ESD region.

The backside contact openings 194 is formed from the backside of the semiconductor IC device 100 through ILD 192 within the logic region and may expose a portion of the bottom surface and/or side surface(s) of a respective backside contact placeholder 162. The backside contact opening 195 is formed from the backside of the semiconductor IC device 100 through ILD 192 within the ESD region and may expose a portion of the bottom surface of the N+ substrate region 116. The backside contact openings 196 is formed from the backside of the semiconductor IC device 100 through ILD 192 within the ESD region and may expose a portion of the bottom surface of the P+ substrate region 117.

The backside contact openings 194, 195, and/or 196 may be formed by a subtractive removal technique, such as an etch, that removes associated portion(s) of the ILD 192. The etch may be timed or otherwise controlled to stop the removal of the ILD 192 in the logic region such that the depth or bottom of backside contact openings 194 exposes the bottom and/or side surfaces of the associated backside contact placeholder 162. The etch may utilize the N+ substrate region 116 and/or P+ substrate region 117 in the ESD region as an etch stop in the ESD region.

The backside contact openings 194, 195, and/or 196 may be formed by the same or shared lithography and etch process, or sequential lithography and etch processes. In such process(es), a mask may be applied and patterned. An opening in the patterned mask may expose the portion of the underlying ILD 192 to be removed while other protected portions of semiconductor IC device 100 thereunder may be protected and retained. In such process(es), the dry and wet etching processes can have etching parameters that can be tuned, such as etchants used, etching temperature, etching solution concentration, etching pressure, source power, RF bias voltage, RF bias power, etchant flow rate, and other suitable parameters and selective materials are utilized to promote the etchant for desired material removal.

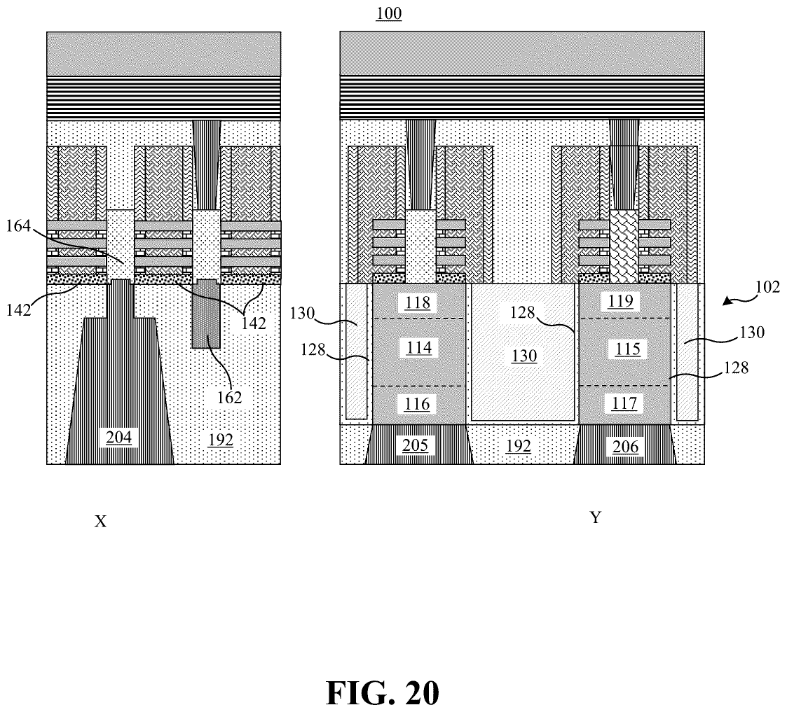

FIG. 20 depicts cross-sectional views of semiconductor IC device 100 shown after exemplary fabrication operation(s), in accordance with one or more embodiments. In the depicted fabrication stage, one or more of respective backside contact placeholder(s) 162 that are exposed by backside contact openings 194 may be removed. Upon removal of the backside contact placeholder(s) 162 by a substrative removal technique, such as an etch, the S/D region 164 there above is at least partially exposed. Further in the depicted fabrication stage, backside contact 204 may be formed within the logic region, backside contact 205 may be formed within the ESD region, and backside contact 206 may be formed within the ESD region.

The backside contact 204 may be formed in contact with or melded against the exposed portion of the S/D region 164 there above. The backside contact 205 may be formed in in contact with or melded against the exposed portion of the N+ substrate region 116 and the backside contact 206 may be formed in in contact with or melded against the exposed portion of the P+ substrate region 117.

The backside contacts 204, 205, and/or 206 may be formed by depositing conductive material, such as metal into the respective backside contact openings. In an example, the backside contacts 204, 205, and/or 206 may be formed by depositing a silicide liner, such as Ni, NiPt or Ti, etc. into the backside contact openings, depositing a metal adhesion liner, such as TiN, TaN, etc. upon the silicide liner, and by depositing a conductive metal fill, such as Al, Ru, W, Co, Cu, etc. upon the metal adhesion liner. Subsequently, a planarization process, such as a CMP process or a mechanical grinding process, may remove excess portions of the conductive barrier layer and the conductive material. Subsequently, the respective bottom surfaces (as depicted) of backside contacts 204, 205, and/or 206 and ILD 192 may be coplanar.

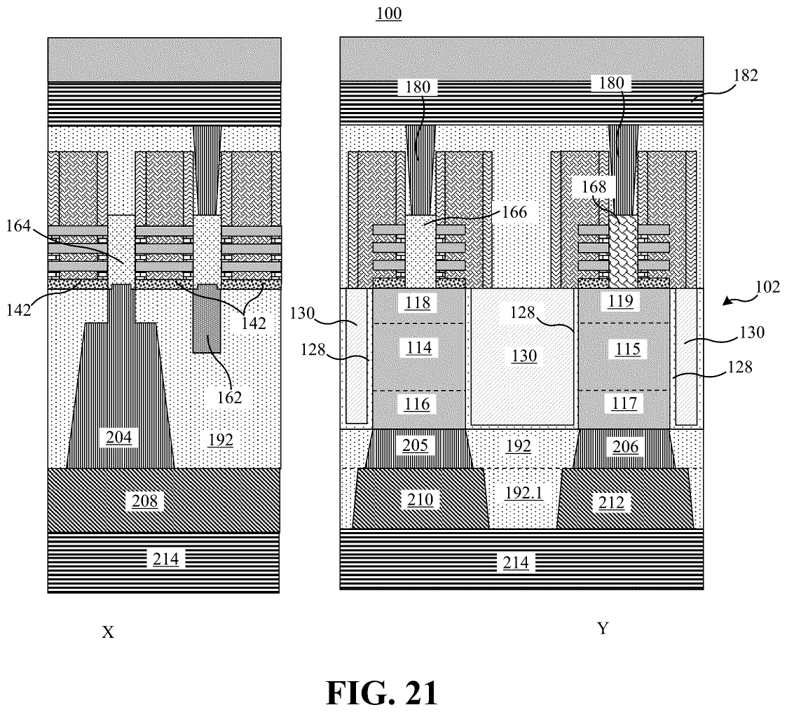

In some examples, backside contacts 204, 205, and/or 206 may be a contact feature, such as a via to a backside rail 208, backside rail 210, or backside rail 212, respectively shown in FIG. 21, such as a backside wiring line, backside power plane, or the like.

FIG. 21 depicts cross-sectional views of semiconductor IC device 100 shown after exemplary fabrication operation(s), in accordance with one or more embodiments. In the depicted fabrication stage, ILD 192.1 is formed, backside rail 208 may be formed within the logic region, backside rail 210 may be formed within the ESD region, backside rail 212 may be formed within the ESD region, and BSPDN 214 is formed upon the backside rails 208, 210, and 212.

The ILD 192.1 may be formed upon the bottom surface of ILD 192 and the other bottom surfaces of the semiconductor IC device 100, as depicted in FIG. 20. The ILD 192.1 may be formed by depositing a dielectric material, such as, for example, porous silicates, carbon doped oxides, silicon dioxides, silicon nitrides, silicon oxynitrides, or other dielectric materials. Any known manner of forming the ILD 192.1 can be utilized. The ILD 192.1 can be formed using, for example, CVD, PECVD, ALD, flowable CVD, spin-on dielectrics, or PVD.

Subsequently, backside rails 208, 210, and/or 212 may be fabricated by forming a respective backside rail trench within ILD 192.1 that exposes at least a portion of backside contacts 204, 205, and/or 206 and depositing conductive material within the backside rail trench over the associated backside contacts 204, 205, and/or 206. The backside rail trenches may expose the entire bottom surface of the respective backside contacts 204, 205, and/or 206. Backside rails 208, 210, and/or 212 may directly contact at least the exposed bottom surface of the associated backside contacts 204, 205, and/or 206.

Backside rails 208, 210, and/or 212 may consist of a metal, such as copper, aluminum, tungsten, cobalt, metal alloys thereof, or the like. In some examples, backside rail 208 may be a power plane or power rail (e.g., VDD power plane, etc.) in the logic region, backside rail 210 may be a power plane or power rail (e.g., VDD power plane, etc.) in the ESD region, and backside rail 212 may be a ground plane or ground rail (e.g., VSS power plane, etc.) in the ESD region.

Backside rails 208, 210, and/or 212 may include a conductive region and a conductive barrier layer(s) between the conductive regions and the ILD 192.1 and/or ILD 190. The conductive barrier layer(s) may be formed of titanium, titanium nitride, tantalum, tantalum nitride, cobalt, a combination thereof, or the like. The conductive regions may be formed of metals such as copper, aluminum, tungsten, cobalt, alloys thereof, or the like. The formation of backside rails 208, 210, and/or 212 may include etching the ILD 192.1 to form a respective trench opening, forming a blanket conductive barrier layer extending into the trench openings, depositing a metallic or conductive material over the blanket conductive barrier layer, and performing a planarization process, such as a CMP process or a mechanical grinding process, to remove excess portions of the conductive barrier layer and the conductive material.

Subsequently, the bottom surface (as depicted) of backside rails 208, 210, and/or 212 and the bottom surface of ILD 192.1 may be coplanar.

BSPDN 214 includes power distribution network features and/or structures to adequately provide VDD potential to backside rail 208 and to backside rail 210 and to also adequately provide VSS potential to backside rail 212. A backside power rail is defined herein as a conductive wiring feature that is configured to electrically carry power potential that is to not change or is otherwise static over time. A backside ground rail is defined herein as a conductive wiring feature that is configured to electrically carry ground potential that is to not change or is otherwise static over time.

BSPDN 214 includes metallization levels, associated metallization dielectric or passivation layers, vertical vias that connect the metallization feature(s) within the metallization levels with an underlying device or structure, or the like. BSPDN 214 include a respective same or different power rails, such as backside rail 208, backside rail 210, or the like, that is formed over backside contacts making electrical contact therewith. One or more power rails within the BSPDN 214 may be connected to S/D region(s) 164 within the logic region by one or more appropriate and associated backside contact(s) 204.

In some examples, there may be five metal levels M0-M4 within BSPDN 214. In some examples, there may be more than ten metal levels M0-Mx within BSPDN 214. In some examples, backside contacts 204, 205, 206 may contact and connect the respective S/D region 164, ESD region 166, or ESD region 168 to a via, trace, signal line, power rail, respectively within the lowest BSPDN 214 metal level M0. Generally, the BSPDN 214 are located on the backside of the semiconductor IC device 102.

For clarity, the semiconductor IC device 100 includes a first diode and a second diode. The cathode of the first diode is connected to backside rail 210 that has a VDD potential, as controlled by the BSPDN 214. The anode of the second diode is connected to backside rail 212 that has a VSS potential, as controlled by the BSPDN 214. The first diode and the second diode are also connected to frontside BEOL structure(s) 182, such as an the same I/O pad, the same wire, rail, trace, or the like. This ESD protection structure with the ESD region may be cooperated with a turn-on efficient power-rail ESD clamp circuit (not shown) to discharge ESD current within the semiconductor IC device 100.

The first diode may include or consist of the N− well substrate region 114, the N+ substrate region 116, the P+ substrate region 118, and a P+ ESD region 166. The second diode may include or consist of a P− well substrate region 115, the P+ substrate region 117, the N+ substrate region 9, and an N+ ESD region 168.

P+ ESD region 166 may be the anode of the first diode and may be connected to the frontside BEOL structure(s) 182 by a first frontside contact 180. N+ ESD region 168 may be the cathode of the second diode and may be connected to the frontside BEOL structure(s) 182 by a second frontside contact 180. The frontside BEOL structure(s) 182 may be the same wire or a same node within the frontside BEOL wiring network. In an alternative implementation, frontside BEOL structure(s) 182 may be different wires or different nodes within the frontside BEOL wiring network that are connected by an I/O pad.

N+ substrate region 116 may be connected to a backside rail 210 by backside contact 205 and P+ substrate region 117 may be connected to backside rail 212 by backside contact 206. Backside rail 210 and 212 are a part of the BSPDN 214 of the ESD protection structure with the ESD region of semiconductor IC device 100. Backside rail 210 may be connected to other backside power wire(s) or structure(s) of the same relative potential, within the BSPDN 214. Likewise, backside rail 212 may be connected to other backside power wire(s) or structure(s) of the same relative potential, within the BSPDN 214.

In an alternative substrate region arrangement, as depicted in FIG. 23, P+ substrate region 118 and N+ substrate region 119 may be removed. In this implementation, N− well substrate region 114 is connected to P+ ESD region 166 and P− well substrate region 115 is connected to N+ ESD region 168.

Semiconductor IC device 100 may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

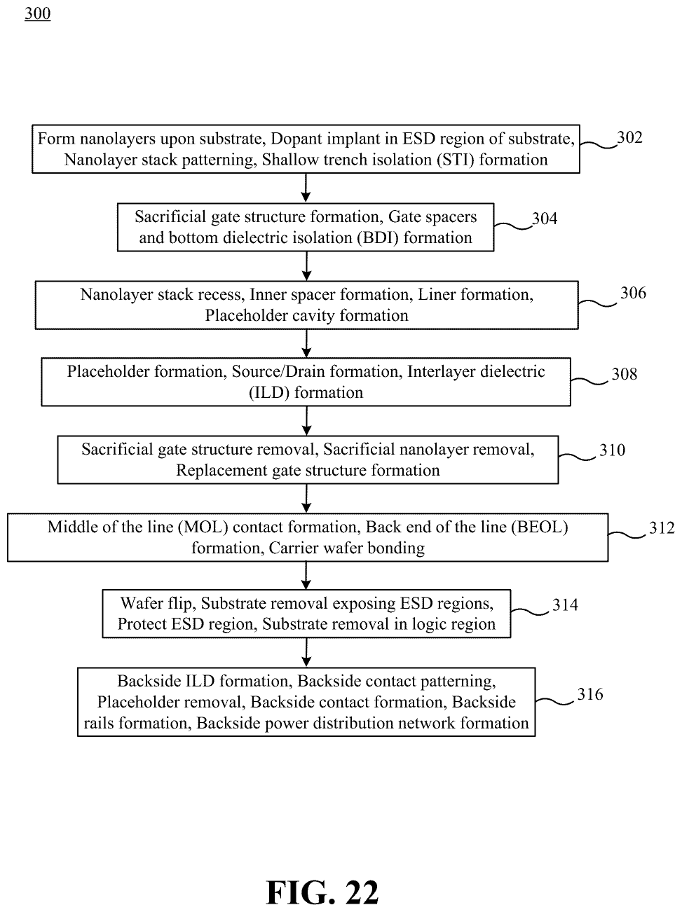

FIG. 22 depicts a flow diagram illustrating method 300 of fabricating FIG. 22 depicts a flow diagram illustrating a fabrication method to fabricate the semiconductor IC device 100 that includes the ESD protection device that uses a BSPDN, according to one or more embodiments of the present disclosure. The depicted fabrication operations of method 300 are illustrated and described above with reference to one or more of FIG. 1 through FIG. 21 of the drawings. The method 300 depicted herein is exemplary. There can be many variations to the diagram or operations described therein without departing from the spirit of the embodiments. For instance, the operations can be performed in a differing order, or operations can be added, deleted, or modified.

At block 302, method 300 may begin with forming nanolayers upon a substrate, implanting or incorporating dopants in an ESD region of the substrate, patterning the nanolayers into one or more nanolayer stacks, and forming one or more STI region(s). For example, method 300 may include initially fabricating a sacrificial nanolayer 104 upon upper substrate 102. Next, an alternating series of sacrificial nanolayers 106 and active nanolayers 108 may be formed upon the sacrificial nanolayer 104. Further, method 300 may include adding dopants within the upper substrate 102 to form a N− well substrate region 114, an N+ substrate region 116, a P+ substrate region 118, a P− well substrate region 115, a P+ substrate region 117, and/or N+ substrate region 119. In some examples, such as that depicted in FIG. 23, dopants are added within the upper substrate 102 to form a N− well substrate region 114, an N+ substrate region 116, a P− well substrate region 115, and/or a P+ substrate region 117. Further, method 300 may include pattering the nanolayers to form one or more nanolayer stack(s) 120 in the logic region and pattering the nanolayers into nanosheet stack 122 and nanosheet stack 123 in the ESD region. Further, method 300 may include forming STI region(s) within the upper substrate 102 next to nanolayer stacks 120, 122, and/or 123.

At block 304, method 300 may further continue with forming one or more sacrificial gate structure(s), forming one or more gate spacers upon the one or more sacrificial gate structure(s), and with forming a BDI. For example, method 300 may include forming one or more sacrificial gate structures 134 upon the STI region(s) and upon and around the nanolayer stacks 120, 122, and/or 123. Further, method 300 may include removing sacrificial nanolayer 104. Further, method 300 may include forming one or more bottom dielectric isolation(s) (BDI) 142 in place of the removed sacrificial nanolayer 104 and with forming one or more spacer(s) 140 upon the sidewall(s) of the sacrificial gate structures 134. The BDI(s) 142 and spacer(s) 140 may be respectively formed upon substrate 102, may be formed upon STI region(s), may be formed upon and around nanolayer stacks 120, 122, and/or 123, and may be formed upon and around the one or more sacrificial gate structure(s) 134, respectively.

At block 306, method 300 may further continue with recessing or indenting the sacrificial nanolayers within the nanolayer stacks, with forming a respective inner spacer within the recesses or indent, with forming a protective liner, and with forming a placeholder cavity. For example, method 300 may include forming S/D recesses 150 within within the nanolayer stack 120 between spacers 140 associated with neighboring sacrificial gate structures 134 in the logic region and ESD recesses 152 are formed within the nanolayer stacks 122, 123 between spacers 140 associated with neighboring sacrificial gate structures 134 in the ESD region. Further, method 300 may include indenting the sacrificial nanolayers 106 within nanolayer stacks 120, 122, and/or 123, thereby forming an indent void. Method 300 may further include forming an inner spacer 144 within a respective indent void. Method 300 may further include forming blanket liner 150 and with forming mask 160 over the ESD region.

At block 308, method 300 may further continue with forming one or more backside contact placeholder structures, with forming one or more S/D structures within the logic region, with forming one or more ESD structures within the ESD region, and with forming an ILD within the logic region and within the ESD region. For example, method 300 may include forming or more backside contact placeholder(s) 162 within upper substrate 102 in the logic region while the mask 160 is protecting the ESD region. Next, method 300 may include removing the mask 160. Further, method 300 may include forming a S/D region 164 upon a respective backside contact placeholder 162 within the logic region and with forming ESD region 166 and ESD region 168 within the ESD region. Still further, method 300 may include forming ILD 176 upon S/D regions 164, ESD region 166, ESD region 168, and/or upon the STI region(s).

At block 310, method 300 may continue with removing the one or more sacrificial gate structure(s), with removing the sacrificial nanolayers, and with forming a replacement gate structure within the void or recess formed by the absence of a respective sacrificial gate structure. For example, method 300 may include removing the sacrificial gate structure(s) 134 and with removing the sacrificial nanolayers 106 and forming a respective replacement gate structure 170 in place of a respective sacrificial gate structure 134 within the logic region and within the ESD region around the active semiconductor nanolayers 108.

At block 312, method 300 may continue with MOL contact formation, with frontside BEOL structure(s) formation, and with bonding a carrier wafer thereto. For example, method 300 may include forming ILD 176.1 upon the replacement gate structure(s) 170 and upon the ILD 170, with forming a respective frontside contact 180 upon one or more S/D regions 164, with forming a respective frontside contact 180 upon ESD region 166, and with forming a respective frontside contact 180 upon ESD region 168. Further, method 300 may include forming frontside BEOL structure(s) 182 and bonding carrier wafer 184 thereto.

At block 314, method 300 may continue with flipping the wafer assembly, with removing the substrate from the backside to expose the appropriate doped ESD substrate regions, with forming a mask to protect the ESD region, and with continued substrate removal in the logic region. For example, method 300 may include flipping semiconductor IC device 100 is flipped using the carrier wafer 182 and removing lower substrate 101. Further, method 300 may include removing etch stop layer 103 to expose the upper substrate 102. Upon removal of the etch stop layer 103, upper substrate 102, the N+ substrate region 116, the P+ substrate region 117, and the STI region(s) may be exposed. Even further, method 300 may also include protecting the ESD region by forming mask 190 thereupon and with removing the upper substrate 102 within the logic region while the ESD region is protected.

At block 316, method 300 may continue with forming a backside ILD, with patterning the backside ILD to form one or more backside contact trenches, with removing one or more of the backside contact placeholder structures, with forming a backside contact within the one or more backside contact trenches, with forming one or more backside rails, and with forming the BSPDN. For example, method 300 may include forming ILD 192 within the logic region and within the ESD region.

Still further, method 300 may include forming backside contact opening 194 within the logic region, forming backside contact opening 195 within the ESD region, and forming backside contact opening 196 within the ESD region. The formation of backside contact opening 194 may exposed one or more of respective backside contact placeholder(s) 162 and may be subsequently removed by a substrative removal technique, such as an etch. Upon removal of the backside contact placeholder(s) 162, the S/D region 164 there above is at least partially exposed.

Still further, method 300 may include forming backside contact 204 within backside contact opening 194 in the logic region, may include forming backside contact 205 within backside contact opening 195 in the ESD region, and may include forming backside contact 206 within backside contact opening 196 in the ESD region. The backside contact 204 may be formed in contact with or melded against the exposed portion of the S/D region 164 there above. The backside contact 205 may be formed in in contact with or melded against the exposed portion of the N+ substrate region 116 and the backside contact 206 may be formed in in contact with or melded against the exposed portion of the P+ substrate region 117.

Still further, method 300 may include forming ILD 192.1, forming backside rail 208 within the ILD 192.1 in the logic region, forming backside rail 210 within the ILD 192.1 in the ESD region, and forming backside rail 212 within ILD 192.1 in the ESD region. Still further, method 300 may include forming BSPDN 214 upon the backside rails 208, 210, and 212.

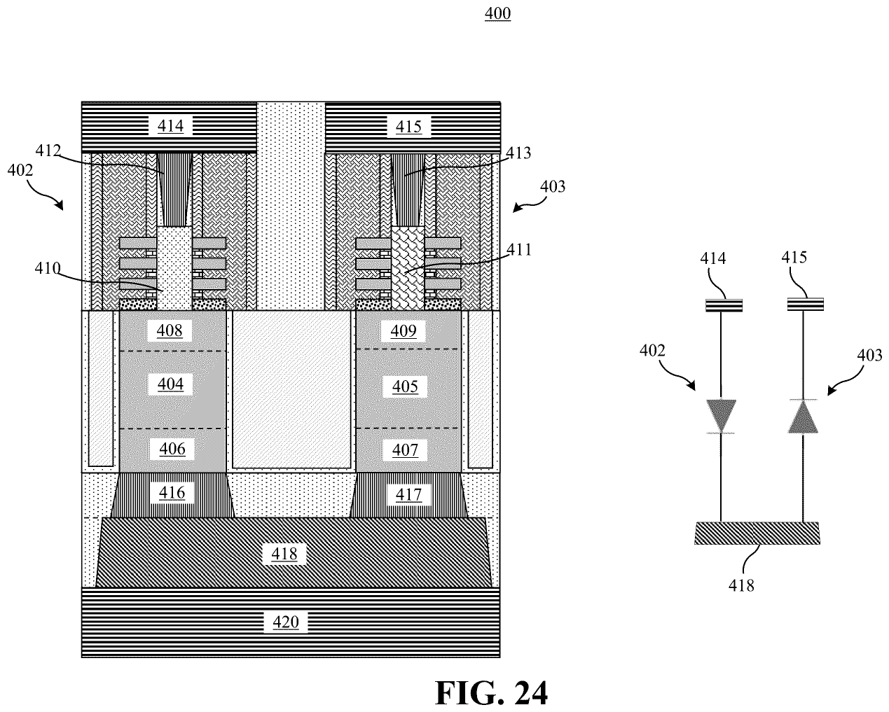

FIG. 24 depicts a semiconductor IC device that includes a diode structure and circuit 400 that uses a BSPDN 420, in accordance with one or more embodiments of the disclosure. The diode structure and circuit 400 includes a diode 402 and diode 403. The cathode of diode 402 and the anode of diode 403 are connected to the same power rail 418 (as depicted) or different power rails with the same relative logical potential (e.g., VDD potential or VSS potential) within the BSPDN 420. The anode of diode 402 and the cathode of diode 4033 are connected indirectly or directly to a same conductive pathway within the BEOL structure 30, such as an the same I/O pad, the same I/O wire, or the like.

Diode 402 may include an N− well substrate region 404, an N+ substrate region 406, a P+ substrate region 408, and/or a P+ device region 410. Similarly, diode 403 may include a P− well substrate region 405, a P+ substrate region 407, a N+ substrate region 409, and/or a N+ device region 411. N− well substrate region 404 and P− well substrate region 405 may be respective doped regions of a substrate.

The N+ substrate region 406 may be vertically below and adjacent to the N− well substrate region 404 and the P+ substrate region 408 may be vertically above and adjacent to the N− well substrate region 404. In this manner, the N+ substrate region 406, N− well substrate region 404, and the P+ substrate region 408 may form a vertical diode stack. Similarly, the P+ substrate region 407 may be vertically below and adjacent to the P− well substrate region 405 and the N+ substrate region 409 may be vertically above and adjacent to the P− well substrate region 405. In this manner, the P+ substrate region 407, P− well substrate region 405, and the N+ substrate region 409 may form a vertical diode stack. These respective substrate regions that are not in the same diode stack may be separated by one or more shallow trench isolation (STI) regions. P+ device region 410 may be vertically above and connected to the P+ substrate region 408 and N+ device region 411 may be vertically above and connected to the N+ substrate region 409.

P+ device region 410 may be connected to a frontside back end of the line (BEOL) wiring network 414 by a contact 412. N+ device region 411 may be connected to a frontside BEOL wiring network 15 by a contact 413. The BEOL wiring network 414 and the BEOL wiring network 415 are generally within the same frontside BEOL network. In one implementation, BEOL wiring network 414 and BEOL wiring network 415 are the same wire or a same node within the frontside BEOL wiring network. In an alternative implementation, BEOL wiring network 414 and BEOL wiring network 415 may be different wires or different nodes within the frontside BEOL wiring network. BEOL wiring network 414 and BEOL wiring network 415 may carry the same signal or relatively different signals.

N+ substrate region 406 may be connected to a backside power rail 418 by a contact 416 and P+ substrate region 407 may be connected to the same backside power rail 418 (or a different power rail of the same logical potential) by a contact 417. Backside power wire 418 are a part of the BSPDN 420 of the diode structure and circuit 400. Backside power wire 418 may be connected to other backside power wire(s) or structure(s) 420 of the same relative potential, within the BSPDN.

The descriptions of the various embodiments of the present disclosure have been presented for purposes of illustration but are not intended to be exhaustive or limited to the embodiments described. Many modifications and variations will be apparent to those of ordinary skill in the art without departing from the scope and spirit of the disclosure. The terminology used herein was chosen to best explain the principles of the embodiment, the practical application or technical improvement over technologies found in the marketplace, or to enable others of ordinary skill in the art to understand the embodiments described herein.

Various embodiments of the present disclosure are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” upon layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

For purposes of the description hereinafter, the terms “upper,” “lower,” “right,” “left.” “vertical,” “horizontal,” “top.” “bottom,” and derivatives thereof relate to the described structures and methods, as oriented in the drawing figures. The terms “overlying.” “atop.” “on top.” “positioned on” or “positioned atop” mean that a first element, such as a first structure, is present on a second element, such as a second structure, wherein intervening elements such as an interface structure can be present between the first element and the second element.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

What is claimed is:

1. A electrostatic discharge (ESD) protection device, comprising:
a first diode comprising a first cathode and first anode, the first cathode connected to a first power rail within a backside power distribution network (BSPDN); and
a second diode comprising a second cathode and second anode, the second anode connected to a second power rail within the BSPDN.

2. The ESD protection device of claim 1, wherein the BSPDN provides a VDD potential to the first power rail and provides a VSS potential to the second power rail.

3. The ESD protection device of claim 1, further comprising:
a frontside back end of the line (BEOL) conductive structure electrically connected to the first anode and to the second cathode.

4. The ESD protection device of claim 3, further comprising a substrate, wherein the first diode comprises a first diode stack of doped regions within the substrate, and wherein the second diode comprises a second diode stack of doped regions within the substrate.

5. The ESD protection device of claim 4, wherein the first diode stack comprises a lightly doped n-type well and wherein a highly doped p-type epitaxially grown region is vertically above the first diode stack upon a top surface of the substrate.

6. The ESD protection device of claim 5, wherein the second diode stack comprises a lightly doped p-type well and wherein a highly doped n-type epitaxially grown region is vertically above the second diode stack upon the top surface of the substrate.

7. The ESD protection device of claim 6, further comprising
a first frontside contact upon the highly doped p-type epitaxially grown region; and
a second frontside contact upon the highly doped n-type epitaxially grown region.

8. The ESD protection device of claim 6, wherein the frontside BEOL conductive structure is connected to the first frontside contact and to the second frontside contact.

9. The ESD protection device of claim 4, wherein the first diode stack further comprises a highly doped n-type region below the lightly doped n-type well within the substrate and wherein the second diode stack further comprises a highly doped p-type region below the lightly doped p-type well within the substrate.

10. The ESD protection device of claim 4, further comprising:
a first backside side contact upon the highly doped n-type region, wherein the highly doped n-type region is the first cathode; and
a second backside contact upon the highly doped p-type region, wherein the highly doped p-type region is the second anode.

11. The ESD protection device of claim 10, wherein first backside side contact is connected to the first power rail and wherein the second backside side contact is connected to the second power rail.

12. A semiconductor integrated circuit (IC) device comprising:
a logic region and an electrostatic discharge (ESD) region;
the logic region comprising a first source/drain (S/D), a second S/D, one or more nanolayer channels connected to the first S/D and connected to the second S/D, and a gate structure around the one or more nanolayer channels; and
the ESD region comprising: a first diode and a second diode, the first diode comprising a first anode and a first cathode that is connected to a first power rail within a backside power distribution network (BSPDN), the second diode comprising a second cathode and second anode that is connected to a second power rail within the BSPDN.

13. The semiconductor IC device of claim 12, wherein the BSPDN provides a VDD potential to the first power rail and provides a VSS potential to the second power rail.

14. The semiconductor IC device of claim 12, further comprising:
a frontside back end of the line (BEOL) conductive structure electrically connected to the first anode, to the second cathode, and to the second S/D.

15. The semiconductor IC device of claim 14, wherein the ESD region further comprises a substrate, wherein the first diode comprises a first diode stack of doped regions within the substrate, and wherein the second diode comprises a second diode stack of doped regions within the substrate.

16. The semiconductor IC device of claim 14, wherein the first diode stack comprises a lightly doped n-type well and wherein a highly doped p-type epitaxially grown region is vertically above the first diode stack upon a top surface of the substrate.

17. The semiconductor IC device of claim 16, wherein the second diode stack comprises a lightly doped p-type well and wherein a highly doped n-type epitaxially grown region is vertically above the second diode stack upon the top surface of the substrate.

18. The semiconductor IC device of claim 17,
wherein the ESD region further comprises a first frontside contact upon the highly doped p-type epitaxially grown region and a second frontside contact upon the highly doped n-type epitaxially grown region, and
wherein the logic region further comprises a third frontside contact between the second S/D and the frontside BEOL conductive structure.

19. The semiconductor IC device of claim 18, wherein the first diode stack further comprises a highly doped n-type region below the lightly doped n-type well within the substrate and wherein the second diode stack further comprises a highly doped p-type region below the lightly doped p-type well within the substrate.

20. The semiconductor IC device of claim 19,
wherein the ESD region further comprises a first backside side contact upon the highly doped n-type region and a second backside contact upon the highly doped p-type region; and
wherein the logic region further comprises a third backside contact upon the first S/D region.
